(19) United States
(12) Patent Application Publication
(10) Pub. No.: US 2012/0062338 A1
(43) Pub. Date: Mar. 15, 2012

(54) ELECTROSTATIC CAPACITANCE ELEMENT, METHOD OF MANUFACTURING ELECTROSTATIC CAPACITANCE ELEMENT, AND RESONANCE CIRCUIT

(75) Inventor: Masayoshi Kanno, Kanagawa (JP)

(73) Assignee: Sony Corporation, Tokyo (JP)

(21) Appl. No.: 13/225,608

(22) Filed: Sep. 6, 2011

(30) Foreign Application Priority Data
Sep. 10, 2010 (JP) 2010-203580

(51) Int. Cl. H03H 7/00; H01G 5/04

(52) U.S. Cl. 333/185; 361/292

(57) ABSTRACT

An electrostatic capacitance element includes: a dielectric layer; and a pair of electrodes or a plurality of pairs of electrodes having one electrode formed on one surface of the dielectric layer and the other electrode formed on the other surface of the dielectric layer by interposing the dielectric layer therebetween. The one electrode and the other electrode are arranged such that longitudinal directions of the electrodes intersect with each other. In addition, the one electrode and/or the other electrode have at least two electrode widths. In a case where the one electrode is formed to be relatively shifted with respect to the other electrode, an area of the electrodes overlapping in a thickness direction of the dielectric layer by interposing the dielectric layer can be changed in a continuous manner or a stepwise manner.

### BACKGROUND

The present disclosure relates to an electrostatic capacitance element and a resonance circuit having the same, and more particularly, to an electrostatic capacitance element having a small capacitance, for example, of the pF-order, a method of manufacturing the same, and a resonance circuit having the electrostatic capacitance element.

In the related art, a variable capacitance element that controls a frequency of the input signal or time to change a capacitance by applying a bias signal from the external side has been utilized. As the variable capacitance element, for example, variable capacitance diodes (varicaps), micro electro mechanical systems (MEMS) are available in the market.

In addition, a technique has been proposed, in which the variable capacitance element described above is used as a protection circuit in a noncontact integrated circuit (IC) card (For example, refer to Japanese Unexamined Patent Application Publication No. 08-7059). According to the technology disclosed in Japanese Unexamined Patent Application Publication No. 08-7059, in order to prevent breakdown of a control circuit containing semiconductor devices having a low voltage withstanding property due to an excessively intense receive signal when the noncontact IC card approaches a reader/writer thereof, the variable capacitance element is used as a protection circuit.

FIG. 19 is a block configuration diagram illustrating the noncontact IC card proposed in Japanese Unexamined Patent Application Publication No. 08-7059. According to Japanese Unexamined Patent Application Publication No. 08-7059, a variable capacitance diode 303d is used as the variable capacitance element. In addition, a series circuit containing a bias removal capacitor 303c and a variable capacitance diode 303d is connected in parallel to a resonance circuit containing a coil 303a and a capacitor 303b.

In Japanese Unexamined Patent Application Publication No. 08-7059, the DC voltage Vout obtained by detecting the receive signal using the detector circuit 313 is resistively divided by resistors 314a and 314b. In addition, the resistively-divided DC voltage (the DC voltage applied to the resistor 314b) is applied to the variable capacitance diode 303d through a coil 315 provided to remove variation of the DC voltage to adjust the capacitance of the variable capacitance diode 303d. That is, the resistively-divided DC voltage is used as a control voltage of the variable capacitance diode 303d.

According to Japanese Unexamined Patent Application Publication No. 08-7059, in a case where the receive signal is excessively strong, the capacitance of the variable capacitance diode 303d is reduced by the control voltage, so that the resonant frequency of the receiver antenna 303 increases. A response of the receive signal at the resonant frequency f₀ before the capacitance changes is lowered than that before the capacitance change, and thus, the level of the receive signal is suppressed. According to the technique proposed in Japanese Unexamined Patent Application Publication No. 08-7059, the signal processing unit 320 (control circuit) is protected by the variable capacitance element in this manner.

The inventors have proposed a device using a ferroelectric material as a variable capacitance element (for example, refer to Japanese Unexamined Patent Application Publication No. 2007-287996). Japanese Unexamined Patent Application Publication No. 2007-287996 proposes a variable capacitance element 400 having an electrode structure as shown in FIGS. 20A and 20B, in order to improve a reliability and a productivity. FIG. 20A is a schematic perspective view illustrating the variable capacitance element 400, and FIG. 20B is a cross-sectional configuration view illustrating the variable capacitance element 400. In the variable capacitance element 400 of Japanese Unexamined Patent Application Publication No. 2007-287996, terminals are provided in each of four surfaces of the rectangular dielectric layer 404. Out of the four terminals, two opposite terminals in one side are signal terminals 403a and 403b connected to the signal power source 403, and two opposite terminals in the other side are control terminals 402a and 402b connected to the control power source 402.

As shown in FIG. 20B, the internal side of the variable capacitance element 400 is structured such that a plurality of control electrodes 402c to 402g and a plurality of signal electrodes 403c to 403f are alternately stacked by interposing the dielectric layer 404 therebetween. Specifically, from the bottom layer, a control electrode 402g, a signal electrode 403f, a control electrode 402f, a signal electrode 403e, a control electrode 402e, a signal electrode 403d, a control electrode 402d, a signal electrode 403c, and a control electrode 402c are sequentially stacked by interposing the dielectric layer 404 therebetween. In the example of FIG. 20B, the control electrode 402g, the control electrode 402e, and the control electrode 402c are connected to the one control terminal 402a, and the control electrode 402f and the control electrode 402d are connected to the other control terminal 402b. In addition, the signal electrode 403f and the signal electrode 403d are connected to one signal terminal 403a, and the signal electrode 403e and the signal electrode 403c are connected to the other signal terminal 403b.

In the variable capacitance element 400 disclosed in Japanese Unexamined Patent Application Publication No. 2007-287996, it is possible to individually apply voltages to the control terminal and the signal terminal. Advantageously, since a plurality of signal electrodes and a plurality of control electrodes are stacked in the internal side, it is possible to increase the capacitance with low costs. In addition, the variable capacitance element 400 having the same structure as that of Japanese Unexamined Patent Application Publication No. 2007-287996 can be easily manufactured with low costs. Furthermore, in the variable capacitance element 400 of Japanese Unexamined Patent Application Publication No. 2007-287996, the bias removal capacitor is dispensable.

### SUMMARY

In order to manufacture a variable capacitance element having a small capacitance using a ferroelectric material having a high relative permittivity, it is necessary to increase an inter-electrode distance by thickening the dielectric layer or reduce the area of the opposite electrodes. However, as the dielectric layer is thickened, the electric field intensity applied to the dielectric layer is reduced. Therefore, a control voltage for changing the capacitance of the variable capacitance element increases. Therefore, in order to provide a variable capacitance element that can be operated with a low voltage, it is necessary to reduce the thickness of the dielectric layer.

However, as the thickness of the dielectric layer is reduced, the capacitance increases, and it is necessary to reduce the area of the opposite electrodes. However, due to manufacturing constraints, it is difficult to manufacture the dielectric layer having a small area such as 100 μm or smaller. Therefore, it is difficult to use a small capacitance, such as 1 pF or lower, to the capacitance of a single layer. For this reason, in a case where a variable capacitance element having a small capacitance and a small control voltage is manufactured, it is difficult to provide a different capacitance value by changing the number of stacks of the electrode. Therefore, it is difficult to provide a variety of products of the variable capacitance elements having different capacitance values. Although the variable capacitance element having a different capacitance value can be formed by changing the electrode shape, in this case, it is necessary to provide a mask for forming the electrodes for each variable capacitance element having different capacitance values, and this increases cost.

In the capacitor containing a dielectric layer and only a pair of electrodes with the dielectric layer being interposed therebetween, as in a thin-film capacitor, it is difficult to change the capacitance by changing the number of stacks of the electrode. For this reason, in a case where the thickness of the dielectric layer is constant, capacitors having different capacitances are manufactured by changing the electrode shape. Even in this case, it is necessary to manufacture the mask for forming the electrode for each of the capacitors having different capacitance values, and this increases cost as well.

It is desirable to provide a method of stably manufacturing the electrostatic capacitance element having different capacitances without changing the electrode shape and the number of stacks of the electrode.

According to an embodiment of the disclosure, there is provided an electrostatic capacitance element containing: a dielectric layer; and a pair of electrodes or a plurality of pairs of electrodes having one electrode formed on one surface of the dielectric layer and the other electrode formed on the other surface of the dielectric layer by interposing the dielectric layer therebetween. The one electrode and the other electrode are arranged such that longitudinal directions of the electrodes intersect with each other. In addition, the one electrode and/or the other electrode have at least two electrode widths. In a case where the one electrode is formed to be relatively shifted with respect to the other electrode, an area of the electrodes overlapping in a thickness direction of the dielectric layer by interposing the dielectric layer can be changed in a continuous manner or a stepwise manner.

In the electrostatic capacitance element of the disclosure, when the one electrode is formed to be relatively shifted with respect to the other electrode, it is possible to change the area of the electrodes overlapping in a thickness direction of the dielectric layer by interposing the dielectric layer therebetween. For this reason, it is possible to form the variable capacitance elements having different capacitances using the same electrode shape.

In a method of manufacturing the electrostatic capacitance element according to another embodiment of the disclosure, the one electrode and the other electrode are patterned using a mask while the one electrode and the other electrode are positioned in predetermined locations on a surface of the dielectric layer. The one electrode and/or the other electrode are formed while a location of the mask positioned on the surface of the dielectric layer surface is adjusted such that an electrode area where the one electrode and the other electrode are overlapped in a thickness direction of the dielectric layer has a predetermined area. The electrostatic capacitance element includes: a dielectric layer; and a pair of electrodes or a plurality of pairs of electrodes having one electrode formed on one surface of the dielectric layer and the other electrode formed on the other surface of the dielectric layer by interposing the dielectric layer therebetween. The one electrode and the other electrode are arranged such that longitudinal directions of the electrodes intersect with each other. In addition, the one electrode and/or the other electrode have at least two electrode widths. In a case where the one electrode is formed to be relatively shifted with respect to the other electrode, an area of the electrodes overlapping in a thickness direction of the dielectric layer by interposing the dielectric layer can be changed in a continuous manner or a stepwise manner.

In the method of manufacturing the electrostatic capacitance element of the disclosure, one electrode and/or the other electrode are formed while a location of the mask positioned on the surface of the dielectric layer is adjusted such that an electrode area where the one electrode and the other electrode are overlapped in a thickness direction of the dielectric layer has a predetermined area. By changing the mask position, the capacitance value of the capacitor unit formed in the overlapped area between the one electrode and the other electrode can be adjusted to be a predetermined capacitance value by changing the mask position.

According to still another embodiment of the disclosure, there is provided a resonance circuit containing: a resonance capacitor having an electrostatic capacitance element; and a resonance coil connected to the resonance capacitor. The electrostatic capacitance element includes: a dielectric layer, and a pair of electrodes or a plurality of pairs of electrodes having one electrode formed on one surface of the dielectric layer and the other electrode formed on the other surface of the dielectric layer by interposing the dielectric layer therebetween. The one electrode and the other electrode are arranged such that longitudinal directions of the electrodes intersect with each other. In addition, the one electrode and/or the other electrode have at least two electrode widths. In a case where the one electrode is formed to be relatively shifted with respect to the other electrode, an area of the electrodes overlapping in a thickness direction of the dielectric layer by interposing the dielectric layer can be changed in a continuous manner or a stepwise manner.

According to the embodiments of the disclosure, by adjusting the relative electrode position of a pair of electrodes with the dielectric layer being interposed, it is possible to change the capacitance value of the resulting electrostatic capacitance element. As a result, without changing the electrode shape and the number of stacks of the electrode, it is possible to stably manufacture the electrostatic capacitance element having different capacitances.

### BRIEF DESCRIPTION OF THE DRAWINGS

FIG. 1 is a perspective view illustrating the appearance of a variable capacitance element according to a first embodiment of the disclosure.

FIG. 2 is a circuit diagram illustrating an exemplary variable capacitance element according to the first embodiment of the disclosure.

FIG. 3 is a structural diagram illustrating the variable capacitance element according to a first configuration example of the first embodiment as seen from the z direction.

FIG. 4 is a diagram illustrating a configuration of the layer where the first electrode is formed according to the first embodiment.

FIG. 5 is a diagram illustrating a configuration of the layer where the second electrode is formed according to the first embodiment.

FIGS. 6A and 6B are diagrams illustrating cross sections taken along the lines VIA-VIA and VIB-VIB of FIG. 3.

FIG. 7 is a structural diagram illustrating the variable capacitance element according to a second configuration example of the first embodiment as seen from the z direction.

FIGS. 8A and 8B are diagrams illustrating cross sections taken along the lines VIIIA-VIIIA and VIIIB-VIIIB of FIG. 7.

FIGS. 9A to 9D are manufacturing process diagrams illustrating a method of manufacturing a variable capacitance element according to the first embodiment.

FIG. 10 is a structural diagram illustrating the variable capacitance element according to a comparison example as seen from the z direction.

FIG. 11 is a cross-sectional view illustrating a variable capacitance element according to a third configuration of the first embodiment.

FIG. 12 is a structural diagram illustrating the variable capacitance element according to a first configuration example of the second embodiment as seen from the z direction.

FIG. 13 is a structural diagram illustrating the variable capacitance element according to a second configuration example of the second embodiment as seen from the z direction.

FIG. 14 is a structural diagram illustrating the variable capacitance element according to a first configuration example of the third embodiment as seen from the z direction.

FIG. 15 is a structural diagram illustrating the variable capacitance element according to a second configuration example of the third embodiment as seen from the z direction.

FIG. 16 is a diagram illustrating an exemplary circuit configuration near the variable capacitance element in practice.

FIG. 17 is a diagram illustrating a configuration example of the variable capacitance element obtained by integrating the variable capacitance element and the bias removal capacitor.

FIG. 18 is a block diagram illustrating a receiver (demodulator) circuit unit of the noncontact IC card according to a fourth embodiment of the disclosure.

FIG. 19 is a block diagram illustrating the noncontact IC card of the related art.

FIGS. 20A and 20B are a schematic perspective view and a cross-sectional configuration diagram of the variable capacitance element of the related art.

### DETAILED DESCRIPTION OF EMBODIMENTS

Hereinafter, an exemplary electrostatic capacitance element according to an embodiment of the disclosure will be described with reference to the accompanying drawings in the following sequence. In addition, although a variable capacitance element will be described as the electrostatic capacitance element in the following examples, it is not intended to limit the disclosure.

1. First Embodiment: Variable Capacitance Element
1-1 First Configuration Example
1-2 Second Configuration Example
1-3 Third Configuration Example

2. Second Embodiment: Variable Capacitance Element
2-1 First Configuration Example
2-2 Second Configuration Example

3. Third Embodiment: Variable Capacitance Element
3-1 First Configuration Example
3-2 Second Configuration Example

4. Fourth Embodiment: Resonance circuit

### 1. First Embodiment

### Variable Capacitance Element

In the first embodiment, an exemplary variable capacitance element having a control terminal and a signal terminal for controlling change of the capacitance will be described. In addition, the variable capacitance element of the present embodiment has a pF-order capacitance.

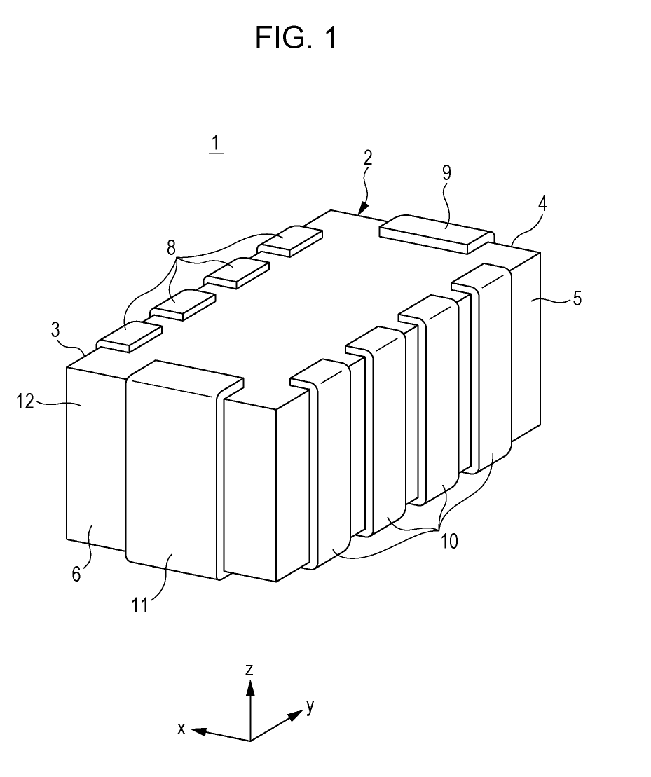

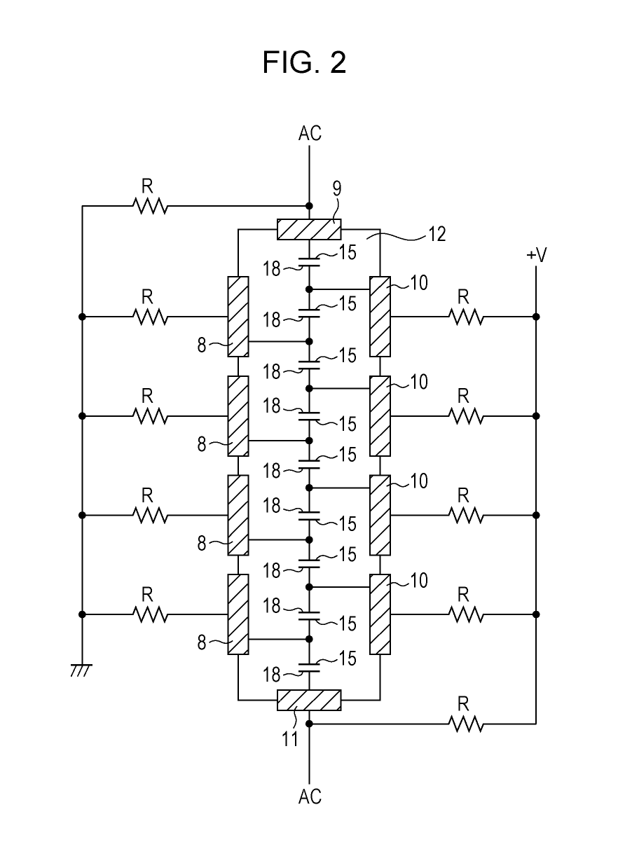

FIG. 1 is a perspective view illustrating appearance of the variable capacitance element 1 of the present embodiment and will be commonly applied to the variable capacitance element in each of the configuration example and the embodiments described below. In addition, FIG. 2 is a circuit diagram illustrating the variable capacitance element 1 of the present embodiment.

The variable capacitance element 1 of the present embodiment includes a ferroelectric layer 12 described below, a laminate 2 having first and second electrodes 15 and 18 described below, first external terminals 8 and 9 connected to the first electrode 15, second external terminals 10 and 11 connected to the second electrode 18.

The laminate 2 is formed to have an approximately rectangular shape. A plurality of first external terminals 8 (four in FIG. 1) are formed in the first side surface 3 of the laminate 2, and the first external terminal 9 is formed in the second side surface 4 neighboring to the first side surface 3. In addition, a plurality of second external terminals 10 (four in FIG. 1) are formed in the third side surface 5 of the laminate 2, and the first external terminal 11 is formed in the fourth side surface neighboring to the third side surface 5. Furthermore, such first and second external terminals 8 and 9, and 10 and 11 are formed to be partially projected from the upper and lower surfaces of the laminate 2.

The first external terminals 8 and 9 and the second external terminals 10 and 11 are supplied with a control voltage V and a signal voltage through a bias resistor R from the power source as shown in FIG. 2. In the present embodiment, the first and second external terminals 8 and 10 are used as a control (DC) terminal, and the first and second external terminals 9 and 11 are used as a signal (AC) terminal. Here, the first and second external terminals 9 and 11 are used as both the signal terminal and the control terminal. In addition, a plurality of capacitor units are formed by the first and second electrodes 15 and 18, and the capacitor units are connected in series. In the following description, a stacking direction of each layer in the laminate 2 is denoted by the z direction, the short axis direction on the surface perpendicular to the stack direction is denoted by the x direction, and the long axis direction is denoted by the y direction.

The variable capacitance element 1 of the present embodiment may have a plurality of configurations having different capacitance values by changing the formation positions without changing the electrode shape of the first and second electrodes 15 and 18 included in the capacitor unit. Hereinafter, the first, second, and third configuration examples will be described in this sequence.

### 1-1 First Configuration Example

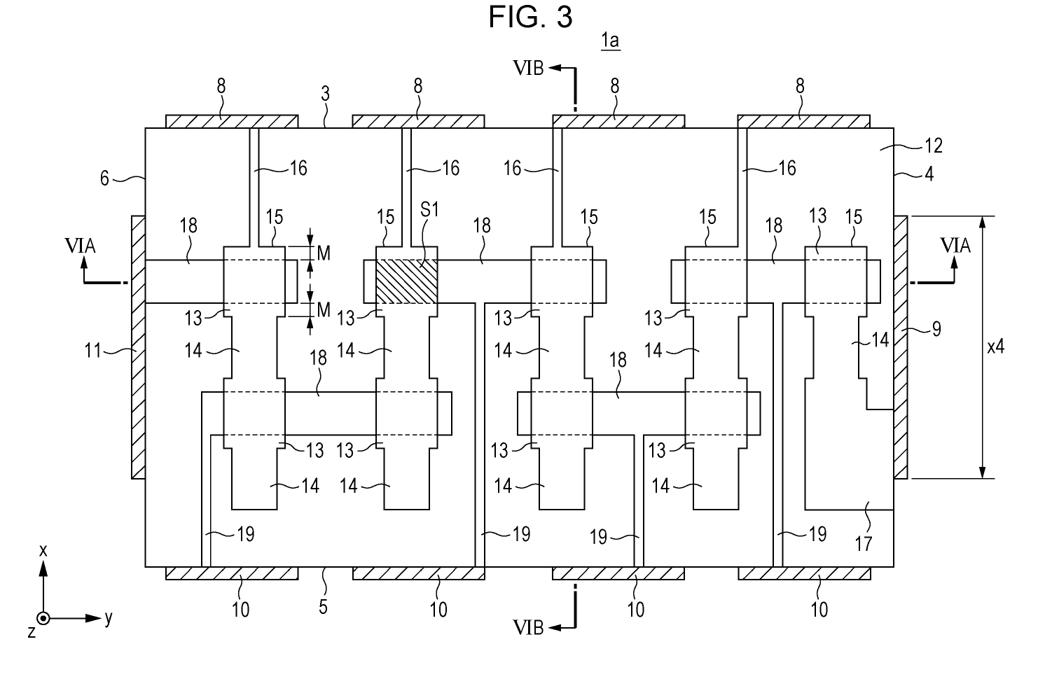

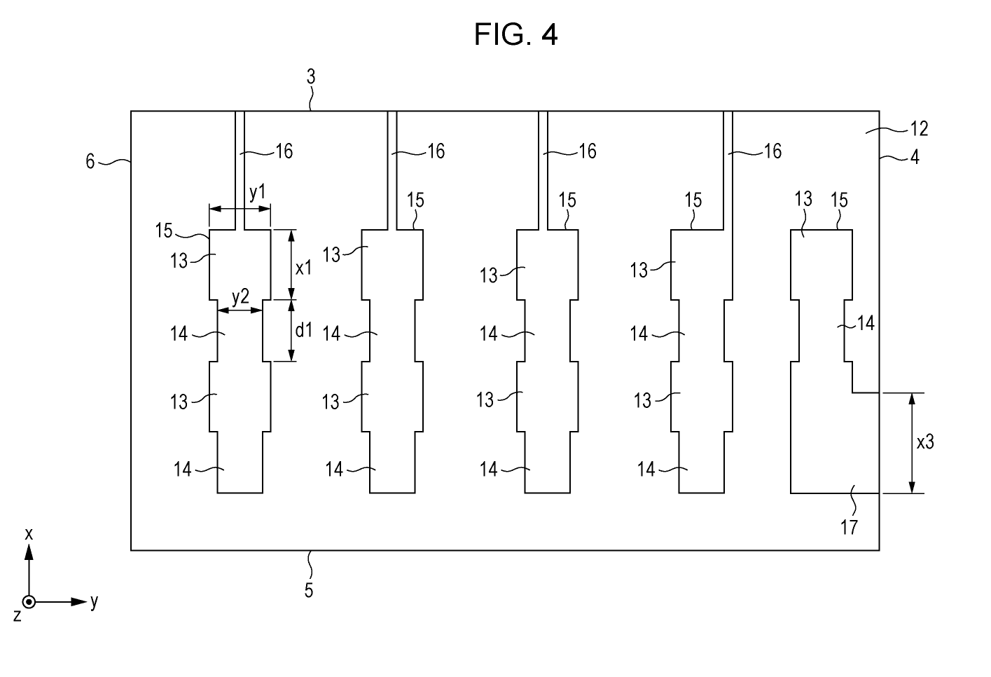

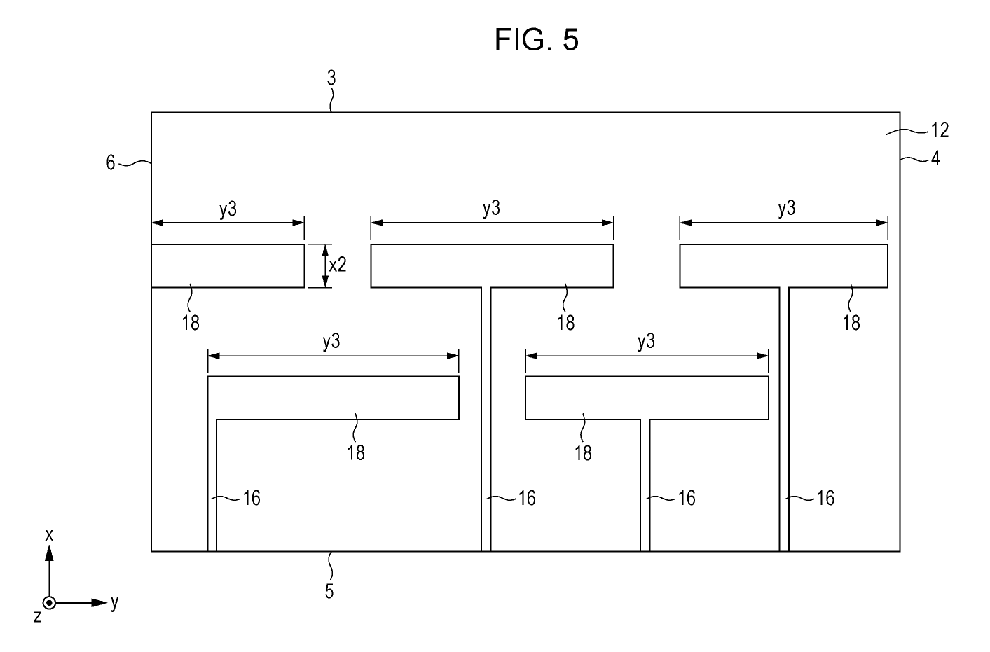

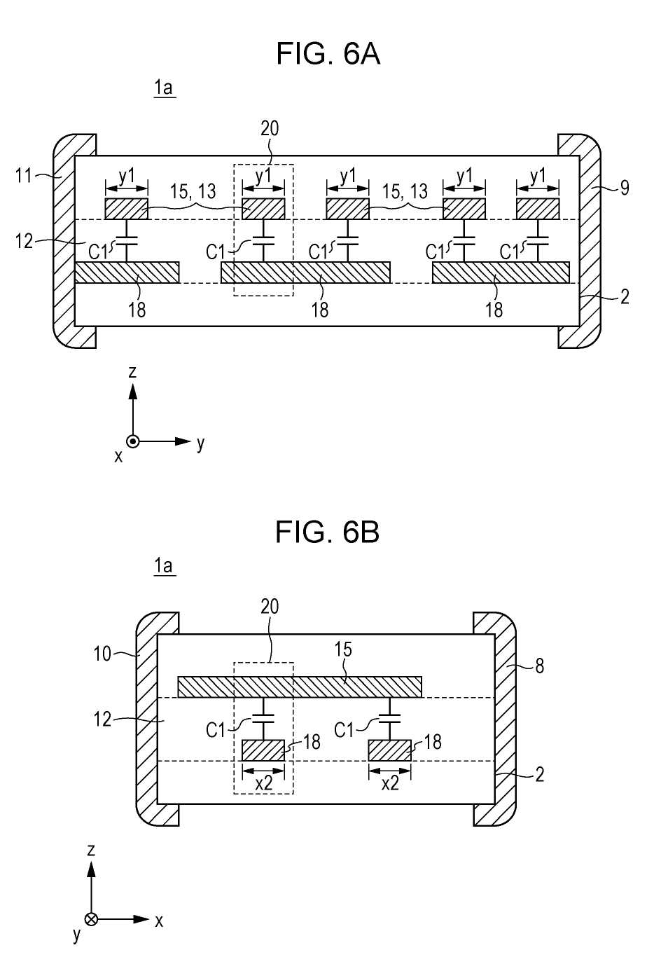

FIG. 3 is a structural diagram illustrating the variable capacitance element 1a according to the first configuration example of the present embodiment as seen from the z direction. In addition, FIG. 4 is a structural diagram illustrating the first electrode of the variable capacitance element 1a as seen from the z direction. FIG. 5 is a structural diagram illustrating the second electrode of the variable capacitance element 1b as seen from z direction. FIG. 6A is a diagram illustrating a cross section taken along the line VIA-VIA of FIG. 3, and FIG. 6B is a diagram illustrating a cross section taken along the line VIB-VIB of FIG. 3.

The variable capacitance element 1a of the present embodiment is provided with a plurality of first electrodes 15 formed on the same plane and a plurality of second electrodes 18 formed on the same plane by interposing a ferroelectric layer 12 therebetween. In addition, the variable capacitance element 1a has a single ferroelectric layer 12 stacked each on the upper side of the first electrode 15 and on the lower side of the second electrode 18.

The ferroelectric layer 12 (dielectric layer) is formed of a dielectric material of which the capacitance is changed depending on the control signal externally applied. For example, the single ferroelectric layer 12 interposed between the first and second electrodes 15 and 18 may include a sheet-shaped member (for example, having a thickness of 2 μm) formed of a ferroelectric material having a relative permittivity over 1000. The surface where the electrode of the ferroelectric layer 12 is formed and the opposite surface have a rectangular shape, of which a ratio between the longitudinal and lateral sides may be set to, for example, 2:1.

As a material of the ferroelectric layer 12, a ferroelectric material capable of generating ion polarization may be used. The ferroelectric material is made of an ion crystal material and electrically generates ion polarization by displacing atoms of positive and negative ions. The ferroelectric material capable of generating ion polarization can be expressed as a chemical composition ABO₃ (O denotes oxygen) having a perovskite structure assuming A and B denote two predetermined elements. Such a ferroelectric material may include, for example, barium titanate (BaTiO₃), potassium niobate (KNbO₃), lead titanate (PbTiO₃), and the like. In addition, a material of the ferroelectric layer 12 may include, for example, PZT (lead zirconium titanate) obtained by mixing lead zirconate (PbZrO₃) with lead titanate (PbTiO₃).

In addition, a material of the ferroelectric layer 12 may include a ferroelectric material capable of electron polarization. In such a ferroelectric material, polarization occurs when the electric dipole moment is generated due to the relative shift of positive and negative electric charges. As an example of such a material, rare-earth ferrioxide exhibiting a ferroelectric characteristic by forming a Fe²⁺ charge surface and a Fe³⁺ charger surface to generate electric polarization has been reported in the related art. In this system, it has been reported that a material having a molecular composition (RE).(TM)₂.O₄ (O denotes an oxygen element) has a high dielectric constant, where RE denotes the rare-earth element, and TM denotes an iron group element. In addition, the rare-earth elements may include, for example, Y, Er, Yb, and Lu (particularly, a heavy rare-earth element with Y). The iron group element may include, for example, Fe, Co, and Ni (particularly, Fe). In addition, materials having a composition (RE).(TM)₂.O₄ may include, for example, ErFe₂O₄, LuFe₂O₄, and YFe₂O₄. Furthermore, as a material of the ferroelectric layer 12, a ferroelectric material having anisotropy may be used.

As shown in FIGS. 6A and 6B, a plurality of first electrodes 15 (five in FIG. 3) are formed on the upper surface of the ferroelectric layer 12 stacked in the middle of the laminate 2, being separated by a predetermined distance from one side to the other side. As shown in FIG. 4, each first electrode 15 is configured by alternately connecting, in the x direction, the rectangular-shaped first electrode portion 13 having a y-directional electrode width y1 and an x-directional electrode width x1 and the rectangular-shaped second electrode portion 14 having a y-directional electrode width y2(<y1) and an x-directional electrode width x1. In addition, the four first electrodes 15 sequentially formed from the fourth side surface 6 side of the laminate 2 are configured by alternately connecting, two-by-two, the first electrode portions 13 and the second electrode portions 14. Meanwhile, the first electrode 15 nearest to the second side surface 4 side is configured by connecting, one-by-one, the first electrode portions 13 and the second electrode portions 14.

As described above, since the first electrode 15 includes the first electrode portion 13 and the second electrode portion 14 having a different electrode width in the y direction, each of the first electrodes 15 has two electrode widths in the x direction. In addition, each first electrode portion 13 of the first electrode 15 is horizontal to the y direction, and each second electrode portion 14 is horizontal to the y direction.

In addition, each of the four first electrodes 15 sequentially formed from the fourth side surface 6 side of the laminate 2 is connected to the internal terminal 16 formed in the same layer as that of the first electrode 15 such that it is exposed to the first side surface 3 in the y direction of the laminate 2. The internal terminal 16 is connected to each of the first external terminals 8 formed in the first side surface 3. In addition, the first electrode 15 nearest to the second side surface 4 of the laminate 2 is connected to the internal terminal 17 formed in the upper surface of the ferroelectric layer 12 to expose the second side surface 4 in the x direction of the laminate 2. In addition, such an internal terminal 17 is connected to the first external terminal 9 formed in the second side surface 4 of the laminate 2.

As shown in FIGS. 6A and 6B, a plurality (five in FIG. 3) of second electrodes 18 are formed on the lower surface of the ferroelectric layer 12 stacked in the middle of the laminate 2. As shown in FIG. 5, the second electrode 18 has a rectangular shape, having a y-directional electrode width y3 (>y1) and an x-directional electrode width x2(<x1 and <y3), extending in the y direction. In addition, each second electrode 18 is separated in the x and y directions, and its longitudinal direction is perpendicular to the longitudinal direction of the first electrode 15. In addition, the second electrode 18 is intersected with a single first electrode 15 or arranged across two first electrodes 15 adjacent to the y direction so that the second electrode 18 and the first electrode portion 13 of the first electrode 15 are overlapped with each other in the z direction.

Four second electrodes 18 sequentially formed from the second side surface 4 side of the laminate 2 are connected to each of the internal terminal 19 formed in the same layer as that of the second electrode 18 such that it is exposed to the third side surface 5 opposite to the first side surface 3 of the laminate 2. In addition, the internal terminal 19 is connected to the second external terminal 10 formed in the third side surface 5 of the laminate 2. In addition, the second electrode 18 nearest to the fourth side surface 6 of the laminate 2. Furthermore, this second electrode 18 is connected to the second external terminal 11 formed on the fourth side surface 6 of the laminate 2.

Here, as shown in FIG. 3, the odd-numbered second electrodes 18 from the fourth side surface 6 side of the laminate 2 are arranged in the lower layer of the first electrode portion 13 located in the first side surface 3 side, and the even-numbered second electrodes 18 are in the lower layer of the first electrode portion 13 located in the third side surface 5. Furthermore, the odd-numbered second electrodes 18 and the even-numbered second electrodes 18 are arranged so as not to be overlapped in the x direction. Through such a layout of the electrodes, it is possible to easily extract each internal terminal 19 connected to the second electrodes 18. Although FIG. 3 illustrates an example in which the odd-numbered second electrodes 18 are arranged in the first side surface 3 side of the laminate 2, and the even-numbered second electrodes 18 are arranged in the third side surface 5 side, the positions thereof may be reversed.

In addition, as shown in FIGS. 6A and 6B, in the variable capacitance element 1a according to the first configuration example, the capacitor unit 20 is formed in the area where each first electrode portion 13 of the first electrode 15 and the second electrode 18 stacked on the first electrode portion 13 by interposing the ferroelectric layer 12 therebetween are overlapped in the z direction. In the capacitor unit 20, it is possible to obtain a capacitance C1 between the first electrode portion 13 of the first electrode 15 and the second electrode 18 opposite to the first electrode portion 13. In addition, in the variable capacitance element 1a according to the first configuration example, since the first electrode portion 13 of the first electrode 15 and the second electrode 18 is overlapped in the z direction, the electrode area of each capacitor unit 20 becomes the overlapped area S1(=x2×y1) between the first and second electrodes 15 and 18.

In addition, in the variable capacitance element 1a of the first configuration example, a plurality of first electrodes 15 and a plurality of second electrodes 18 are arranged in the same layer, and a single or two second electrodes 18 are overlapped with a single first electrode 15 in the z direction. As a result, a plurality of capacitor units 20 are formed on the same layer.

### 1-2 Second Configuration Example

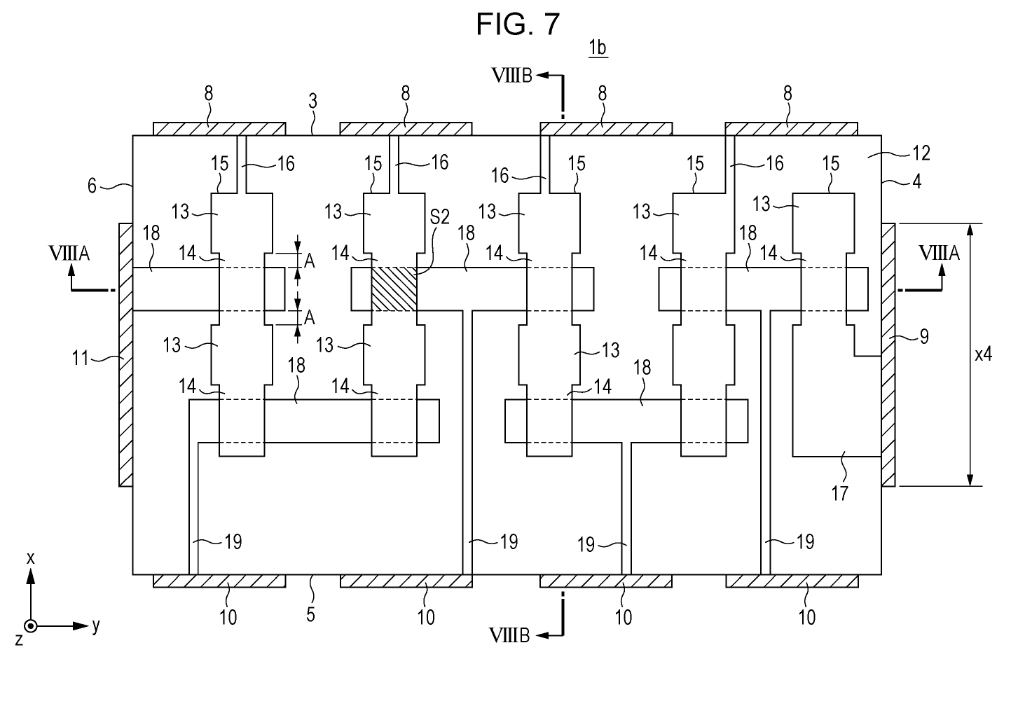

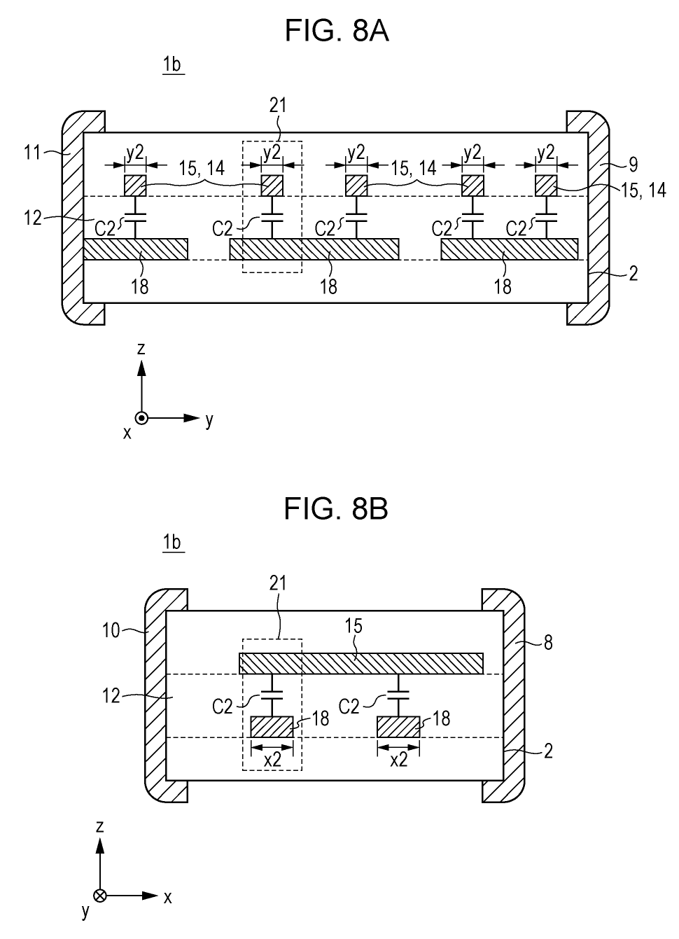

Next, the variable capacitance element 1b according to the second configuration example of the present embodiment will be described. FIG. 7 is a structural diagram illustrating the variable capacitance element 1b according to the second configuration example as seen in the z direction. In addition, FIG. 8A illustrates a cross section taken along the line VIIIA-VIIIA of FIG. 7, and FIG. 8B illustrates a cross section taken along the line VIIIB-VIIIB of FIG. 7. Throughout FIGS. 7, 8A and 8B, like reference numerals denote like elements as in FIGS. 3, 6A and 6B, and description thereof will not be repeated.

In the variable capacitance element 1b of the second configuration example, compared to the variable capacitance element 1a of the first configuration example, the first electrode 15 is shifted to the first side surface side by x1 in the x direction. For this reason, the second electrode 18 is arranged to overlap with the second electrode portion 14 of the first electrode 15 in the z direction by interposing the ferroelectric layer 12 therebetween.

As shown in FIGS. 8A and 8B, in the variable capacitance element 1b according to the second configuration example, the capacitor unit 21 is formed in the area where each second electrode portion 14 of the first electrode 15 and the second electrode 18 stacked on the second electrode portion 14 by interposing the ferroelectric layer 12 therebetween are overlapped in the z direction. Using the capacitor unit 21, it is possible to obtain a capacitance C2 between the second electrode portion 14 of the first electrode 15 and the second electrode 18 opposite to the second electrode portion 14. In addition, in the variable capacitance element 1b according to the second configuration example, since the second electrode portion 14 of the first electrode 15 and the second electrode 18 are overlapped in the z direction, the electrode area of each capacitor unit 21 becomes the overlapped area S2(=x2×y2) between the first and second electrodes 15 and 18.

The y-directional width of the second electrode portion 14 of the first electrode 15 is smaller than the y-directional width of the first electrode portion 13. For this reason, in the variable capacitance element 1b of the second configuration example, the electrode area S2 of each capacitor unit 21 is smaller than the electrode area S1 of each capacitor unit 20 of the variable capacitance element 1a in the first configuration example. As a result, the entire capacitance of the variable capacitance element 1b in the second configuration example becomes smaller than the entire capacitance of the variable capacitance element 1a of the first configuration example.

As such, in the variable capacitance element 1 of the present embodiment, even when the first and second electrodes 15 and 18 have the same shape, it is possible to configure two kinds of variable capacitance elements having different capacitances by relatively shifting the first electrode 15 with respect to the second electrode 18.

In the variable capacitance elements 1a and 1b formed through the first and second configuration examples of the present embodiment, the capacitor unit includes first and second electrodes 15 and 18 formed in the dielectric layer 12, and the capacitor units are connected in series as shown in FIG. 2. A control voltage +V is added to each of the capacitor units by applying a ground voltage GND and a control voltage +V to the capacitor unit through a bias resistor R. Meanwhile, since the signal voltage (AC voltage) passes through 9 capacitor units connected in series, the entire capacitance is reduced by 1/9. However, since the control voltage is individually added to each capacitor unit, even a small value may be acceptable. That is, in the variable capacitance element 1 of the present embodiment, a circuit is designed such that the control voltage is maintained in a suitable range by reducing the capacitance value. In addition, the bias resistance R is, generally, at 500 kΩ to 1 MΩ.

Method of Manufacturing Variable Capacitance Element

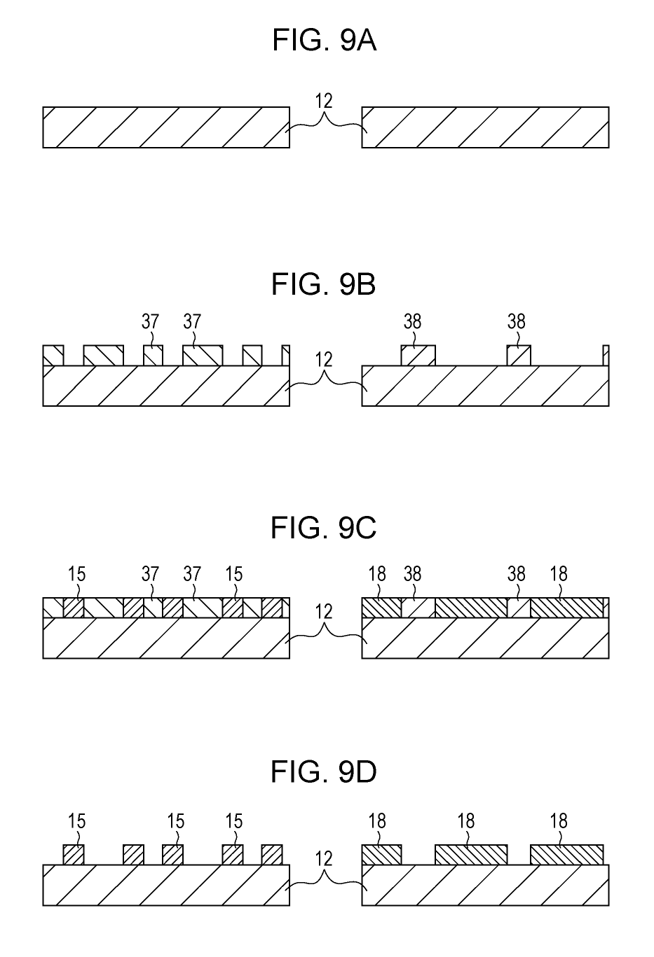

Next, a method of manufacturing variable capacitance elements 1a and 1b according to the first and second configuration examples of the present embodiment will be described. FIGS. 9A to 9D are manufacturing process diagrams of the variable capacitance elements 1a and 1b according to the first and second configuration examples of the present embodiment.

First, as shown in FIG. 9A, a sheet member (two sheets in FIG. 9A) made of the aforementioned ferroelectric material is prepared. Such a sheet member serves as the aforementioned ferroelectric layer 12, of which one surface serves as the ferroelectric layer 12 for forming the first electrode 15 and the other surface serves as the ferroelectric layer 12 for forming the second electrode 18.

Next, conductive paste obtained by pasting metal fine power such as Pd, Pd/Ag, and Ni is adjusted. Additionally, a first mask 37 having openings shaped for the first electrode 15 and a second mask 38 having openings shaped for the second electrode 18 are prepared. Then, as shown in FIG. 9B, the first mask 37 is arranged in a predetermined position on the upper surface of one sheet member (ferroelectric layer 12), and the second mask 38 is arranged in a predetermined position on the upper surface of the other sheet member (ferroelectric layer 12).

Then, as shown in FIG. 9C, the conductive paste is coated (through a serigraph) on the upper side of the one sheet member by interposing the first mask 37, and the conductive paste is coated on the upper side of the other sheet member by interposing the second mask 38. As a result, the conductive paste is coated on the upper side of the sheet member in the openings of each mask. Therefore, the first electrode 15 is patterned on the one sheet metal, and the second electrode 18 is patterned on the other sheet metal.

In addition, as shown in FIG. 9D, the first electrode 15 having the ferroelectric layer 12 and the second electrode 18 having the ferroelectric layer 12 are formed by removing the first and second masks 37 and 38 from the upper sides of each sheet member.

Compared to such a manufacturing method, in a case where the variable capacitance element 1a is manufactured according to the first configuration example, the first and second masks 37 and 38 are positioned with respect to each sheet member such that the second electrode 18 is superimposed on the lower layer of the first electrode portion 13 of the first electrode 15 when the sheet members are overlapped.

Meanwhile, in a case where the variable capacitance element 1b is formed in the second configuration example, the first and second masks 37 and 38 are positioned in each sheet member such that the second electrode 18 is superimposed on the lower layer of the second electrode portion 14 of the first electrode 15 when the sheet members are overlapped. That is, in a case where the variable capacitance element 1b is formed in the second configuration example, the first mask 37 is arranged on the sheet member so as to be deviated toward the side, where the internal terminal 16 is formed, in the x direction by a distance x1 to form the first electrode 15 in comparison with a case where the variable capacitance element 1a is formed in the first configuration example.

Here, the internal terminals 16 of the first electrodes 15 are different in the length between the variable capacitance elements 1a and 1b of the first and second configuration examples, respectively. For this reason, in the manufacturing method of the present embodiment, the openings are formed in the portions corresponding to the internal terminals 16 of the mask such that the internal terminal 16 exposed to the side face of the laminate 2 is formed even when the position of the mask is moved a predetermined distance.

Then, the sheet member where the second electrode 18 (electrode paste layer) is coated and the sheet member where the first electrode 15 (electrode paste layer) is coated are stacked upwardly such that the sheet member and the electrode paste layer are alternated. If necessary, a sheet member having no electrode paste layer is stacked on top of the uppermost first electrode 15 to form a laminate 2 including the sheet member and the conductive paste layer.

Then, the laminate 2 is thermally pressed. The sheet member and the conductive paste layer (first and second electrodes 15 and 18) are integrated into a single body by high-temperature firing the thermally pressed member under a reduction atmosphere. Then, the first external terminals 8 and 9, and the second external terminals 10 and 11 are formed on the first to fourth side surfaces 3 to 6 of the laminate 2 so that the variable capacitance elements 1a and 1b according to the first or second configuration example are completely manufactured.

As such, in the variable capacitance element 1 of the present embodiment, by changing the mask position during the electrode manufacturing, it is possible to form the variable capacitance elements having different capacitances as indicated in the first and second configuration examples.

The method of manufacturing the variable capacitance element of the present embodiment is not limited to the aforementioned one. For example, although the thin-film capacitor is formed such that the electrodes are provided by sputtering Pt and the like on a substrate such as Si and removing unnecessary parts through etching, the positions of the electrodes can be shifted by relatively shifting the position of the mask for etching the unnecessary parts with respect to the upper and lower electrodes.

Overview of Design of Electrode Shape

According to the present embodiment, it is necessary to consider the dimensions of the first and second electrodes 15 and 18 in order to make it possible to configure the variable capacitance elements 1a and 1b having different capacitances by adjusting the formation positions thereof even when they have the same electrode shape. Hereinafter, an overview of the design for shapes and dimensions of the first and second electrodes 15 and 18 of the variable capacitance element 1 according to the present embodiment will be described.

The x-directional electrode width x1 of the first and second electrode portions 13 and 14 of the first electrode 15 preferably has a predetermined width larger than the x-directional electrode width x2 of the second electrode 18 in consideration of undesired position deviations in the manufacturing of the first and second electrodes 15 and 18. As a result, referring to FIG. 3, when the center position of the first electrode 15 in the x direction and the center position of the second electrode 18 in the x direction are matched, a margin M((x1−x2)/2) (the area not overlapping with the second electrode 18) is formed in both ends of the overlapped area S1 in the x direction. Such a margin M preferably has a width capable of absorbing a coupling deviation between the first and second electrodes 15 and 18, and more preferably, for example, of 10 μm or larger. In addition, considering manufacturing constraints, the electrode width x1 is preferably set to 50 μm or larger, and more preferably, 100 μm or larger.

Since the margin M is provided in this manner, for example, in a case where the first electrode 15 is deviated from the second electrode 18 from a predetermined position in the x direction, if the deviation amount is smaller than the width of the margin M, the overlapped area between the first and second electrodes 15 and 18 does not change. For this reason, since it is possible to form the variable capacitance element having a desired capacitance value just by shifting the electrode position in a single direction, it is possible to make it easier to form variable capacitance elements having different capacitance values. In addition, the position of the first electrode is different in the x-directional electrode widths x1 of the first and second electrode portions 13 and 14 between the first and second configuration examples. Such an electrode width x1 is sufficiently large in comparison with the margin M and may be deviated by intentionally changing the mask position. Therefore, in the variable capacitance element 1 of the present embodiment, in the event of a slight coupling deviation, it is possible to change the area where the first and second electrodes 15 and 18 are overlapped only by moving the desired electrode position without changing the overlapped area between the first and second electrodes 15 and 18.

In addition, according to the present embodiment, it is possible to change the variable capacitance element 1a of the first configuration example and the capacitance value of the variable capacitance element 1b of the second configuration example based on a difference of the width in the y direction between the first and second electrode portions 13 and 14 of the first electrode 15. Therefore, by setting a relationship between the electrode widths y1 and y2, for example, to y1:y2=1:0.8, a ratio between the capacitance value of the variable capacitance element 1a of the first configuration example and the capacitance value of the variable capacitance element 1b of the second configuration example may be set to 1:0.8. In the meantime, the electrode widths y1 and y2 may have other values, and various setting may be made.

The y-directional electrode width y3 of the second electrode 18 may be larger than a y-directional maximum electrode width of the first electrode 15, that is, the y-directional electrode width y1 of the first electrode portion 13. In the present embodiment, since the second electrode 18 nearest to the fourth side surface 6 of the laminate 2 is connected to the second external terminal 11 of the fourth side surface 6, it is not necessary to provide a length so as to be exposed to the side surface of the laminate 2. In addition, since each of other second electrodes 18 is formed across the two first electrodes 15, it is necessary to form the y-directional electrode width y3 to be larger than a y-directional width including the two neighboring first electrodes.

In addition, according to the present embodiment, the second electrode 18 has a rectangular shape, and is arranged such that the longitudinal direction (y direction) thereof is perpendicular to the longitudinal direction (x direction) of the first electrode 15. For this reason, even when the first and second electrodes 15 and 18 are deviated from a predetermined position in the y direction due to a coupling deviation, the overlapped area between the first and second electrodes 15 and 18 does not change. As a result, the capacitance value is rarely changed by the positional deviation in the y direction.

In addition, according to the present embodiment, it is necessary to shift the formation position of the first electrode 15 a predetermined distance in the x direction in the variable capacitance element 1a of the first configuration example and the variable capacitance element 1b of the second configuration example. Such a shift distance is constrained by the length of the external terminal which is constrained by a device size and the x-direction length of the device. For example, if the shift distance is larger than the x-directional length x4 of the first external terminal 9 formed in the second side surface 4 of the laminate 2, it may not possible to connect the internal terminal 17 of the first electrode 15 nearest to the second side surface 4 and the first external terminal 9. For this reason, in the variable capacitance element 1 of the present embodiment, there is a constraint that the shift distance of the first electrode 15 is to be smaller than the length x4 of the first external terminal 9 formed in the second side surface 4 of the laminate 2 in the x direction. Such a constraint may be removed by increasing the width x3 of the internal terminal 17 of the first electrode 15 nearest to the second side surface 4 to be larger than the length x4 of the first external terminal 9 in the x direction. However, in consideration of the ease of manufacturing the electrode and shifting the mask, the shift distance of the first electrode 15 is preferably smaller than the length x4 of the first external terminal 9 in the x direction. In addition, assuming a case that a small-sized variable capacitance element having a width of the laminate 2 in the y direction set to 1.0 mm and a width thereof in the x direction set to 0.5 mm, the length x4 of the first external terminal 9 formed in the second side surface 4 in the x direction becomes 200 to 300 mm. For this reason, the shift distance of the first electrode 15 is preferably set to a range between 100 and 200 mm.

### Comparison Example

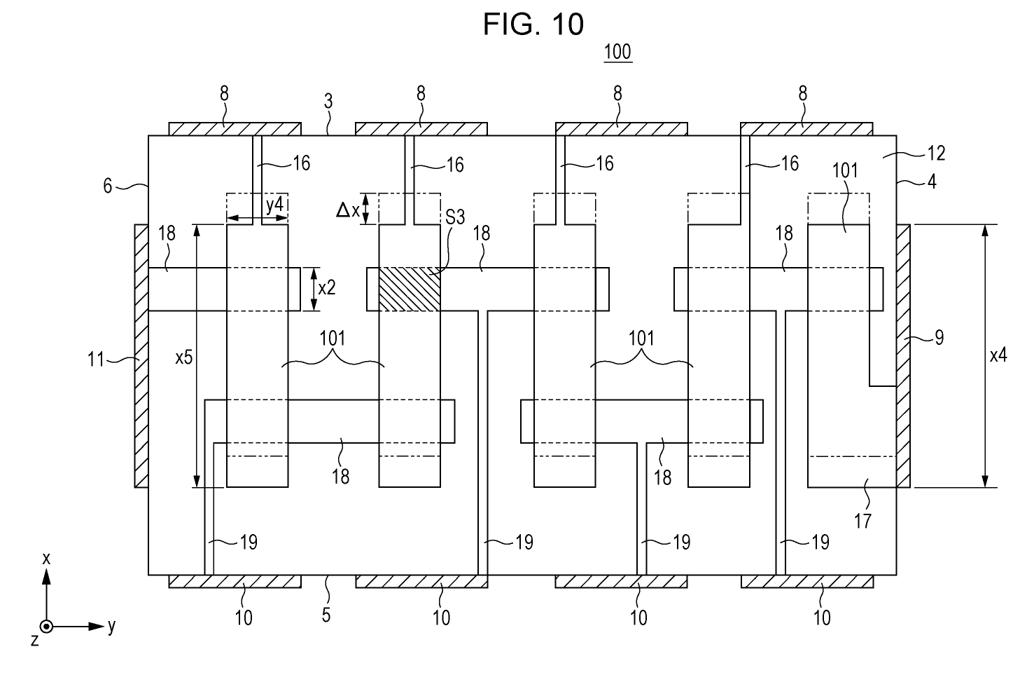

Next, a variable capacitance element according to a comparison example will be described. FIG. 10 is a structural diagram illustrating the variable capacitance element 100 according to the comparison example as seen from the z direction. The appearance of the variable capacitance element 100 according to the comparison example is similar to that of the variable capacitance element 1 according to the present embodiment shown in FIG. 1, and description thereof will not be repeated. In FIG. 10, like reference numerals denote like element as in FIG. 3.

The variable capacitance element 100 according to the comparison example and the variable capacitance element 1 of the present embodiment differ in the shape of the first electrode 101.

As shown in FIG. 10, in the variable capacitance element 100 according to the comparison example, a plurality of first electrodes 101 (five in FIG. 10) are formed on top of the ferroelectric layer 12 stacked in the middle of the laminate 2 while they are separated from each other by a predetermined distance from the one side to the other side in the y direction. Each of the first electrodes 101 is formed to have a rectangular shape having a y-directional electrode width y4 and an x-directional electrode width x5 (>x2).

Out of the five first electrodes 101, the first electrode 101 nearest to the second side surface 4 of the laminate 2 is connected to the first external terminal 9 formed on the second side surface 4 through the internal terminal 17. The remaining first electrodes 101 are respectively connected to the first external terminals 8 formed on the first side surface 3 of the laminate 2 through the internal terminal 16.

In the variable capacitance element 100 according to the comparison example, the second electrode 18 is arranged to intersect with a single first electrode 101 or extending across the neighboring two first electrodes 101. In addition, a capacitor unit is formed in the area where the first and second electrodes 101 and 18 are overlapped in the z direction. The electrode area containing the first and second electrodes 101 and 18 of the capacitor unit corresponds to the overlapped area S3 (=x2×y4) between the first and second electrodes 101 and 18 in the z direction.

In the variable capacitance element 100 of the comparison example, as indicated by a dashed line in FIG. 10, the overlapped area S4 between the first and second electrodes 101 and 18 does not change, for example, even when the first electrode 101 is shifted by a length Δx in the x direction. For this reason, the capacitance value of the capacitor unit containing the first and second electrodes 101 and 18 overlapped in the z direction and the ferroelectric layer 12 formed therebetween does not change. In order to change the capacitance value of the variable capacitance element 100 of the comparison example, it is necessary to change the number of the stacked layers or the shape of the electrode. In order to change the shape of the electrode, it is necessary to form the electrode using another mask, thus increasing cost. In addition, when the corresponding capacitance is larger, and the capacitance value is changed by increasing the number of the stacked layers, the capacitance value may increase, but may not decrease.

Meanwhile, in the variable capacitance element 1 (1a and 1b) of the present embodiment, the first electrode 15 has two or more electrode widths. For this reason, it is possible to easily change the overlapped area between the first and second electrodes 15 and 18 by shifting the mask position a predetermined distance in a single direction (in this case, the x direction) when the first electrode 15 is formed on the surface of the ferroelectric layer 12. As a result, it is possible to the variable capacitance elements 1 (1a and 1b) having different capacitances with the same number of stacked layers. In this case, it is not necessary to change the mask for forming the electrodes or significantly change the manufacturing process. Therefore, it is possible to obtain the variable capacitance element 1 (1a and 1b) having excellent quality with low costs.

According to the present embodiment, the variable capacitance elements 1 (1a and 1b) having different capacitances are configured by shifting the position of the first electrode 15 in the x direction. However, the present disclosure is not limited thereto, but the variable capacitance elements having different capacitance values can be formed by shifting the position of the second electrode 18 in the x direction. That is, if the first and second electrodes 15 and 18 are formed such that the first and second electrodes 15 and 18 are relatively shifted a predetermined distance, it is possible to form the variable capacitance elements having different capacitance values. In addition, according to the present embodiment, since the capacitance can be changed by shifting one of the electrodes a predetermined distance in a single direction, the positioning can be easily made. Such a configuration is particularly effective for making infinitesimal changes to the capacitance value of the variable capacitance element having a capacitance value of the pF-order.

Although, for example, a plurality of capacitor units are included in the same layer by overlapping a plurality of first and second electrodes 15 and 18 in the z direction with the ferroelectric layer 12 being interposed therebetween according to the present embodiment, the capacitor unit may include a pair of first electrode 15 and a single second electrode 18. Furthermore, according to the present embodiment, a plurality of first and second electrodes 15 and 18 may be stacked with the ferroelectric layer 12 being interposed therebetween. For example, a five-layered capacitor unit may be formed by alternately stacking three-layered first electrodes 15 and three-layered second electrodes 18. In the variable capacitance element 1a of the first configuration example, when the capacitance value C1 of a single layer is 9 pF, the capacitance value of the five-layered capacitor unit becomes 45 pF. In addition, in the variable capacitance element 1b of the second configuration example, when the capacitance value C2 of a single layer is 8 pF, the capacitance value of the five-layered capacitor unit becomes 40 pF.

### 1-3 Third Configuration Example

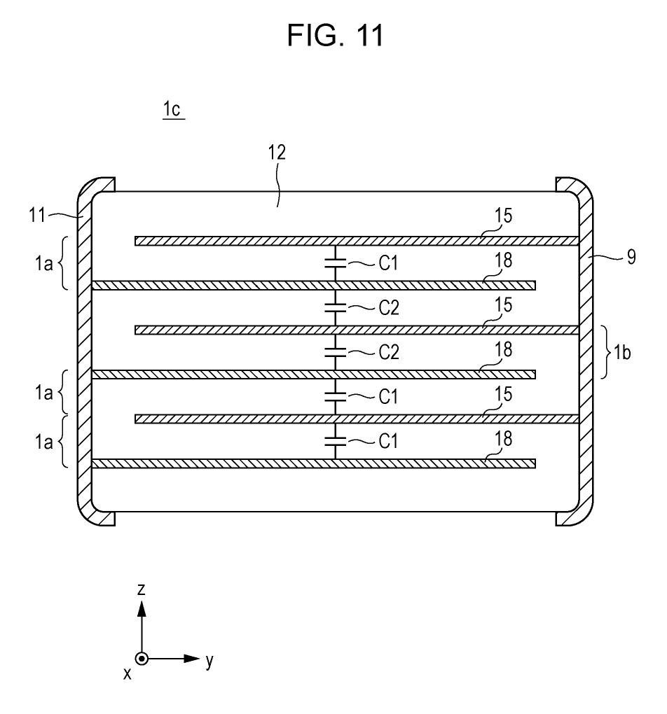

Hereinafter, as a third configuration example, a variable capacitance element formed by stacking a plurality of variable capacitance elements 1a of the first configuration example and a plurality of variable capacitance elements 1b of the second configuration example will be described. FIG. 11 is a diagram illustrating a cross-sectional configuration of the variable capacitance element 1c according to the third configuration example. In FIG. 11, like reference numerals denote like elements as in FIGS. 6A, 6B, 8A, and 8B.

FIG. 11 illustrates a single first electrode 15 and a single second electrode 18 formed in the same layer because they are simple.

As shown in FIG. 11, the variable capacitance element 1c of the third configuration example are configured by alternately stacking three-layered second electrodes 18 and three-layered first electrodes 15. In addition, out of the three-layered first electrodes 15, the underlying first electrode 15 and the overlying first electrode 15 are formed to have the same position as that of the first electrode 15 of the variable capacitance element 1a of the first configuration example with respect to the opposite second electrode 18. Meanwhile, out of the three-layered first electrodes 15, the center first electrode 15 is formed to have the same position as that of the first electrode 15 of the variable capacitance element 1b of the second configuration example with respect to the opposite second electrode 18.

That is, in the variable capacitance element 1c of the third configuration example, the center first electrode 15 is formed to be deviated by the electrode width x1 in the x direction with respect to other two first electrodes 15. As a result, the variable capacitance element 1a shown in the first configuration example using the underlying first electrode 15 and the second electrode 18 opposite thereto is formed to have two layers. In addition, the variable capacitance element 1b shown in the second configuration example using the center first electrode 15 and the second electrode 18 opposite thereto is formed to have two layers. The variable capacitance element 1b shown in the first configuration example using the overlying first electrode 15 and the second electrode 18 opposite thereto is formed to have two layers.

In the aforementioned configuration, for example, if the capacitance value C1 of the variable capacitance element 1a of the first configuration example is set to 9 pF, and the capacitance value C2 of the variable capacitance element 1b of the second configuration example is set to 8 pF, the entire capacitance value becomes 3×9+8×2=43 pF. As such, in the variable capacitance element 1c obtained by alternately stacking the first and second electrodes 15 and 18 as a plurality of layers, if a plurality of the first electrodes 15 have different formation positions, it is possible to set different capacitance values in each layer. In addition, since the number of stacked layers or the number of layers included in the variable capacitance element 1a of the first configuration example, or the number of layers included in the variable capacitance element 1b of the second configuration example can be designed with freedom, it is possible to provide the variable capacitance elements having various capacitance values.

### 2. Second Embodiment

### Variable Capacitance Element

Next, the second embodiment of the disclosure will be described. Appearance of the variable capacitance element of the present embodiment is similar to that of FIG. 1, and description thereof will not be repeated. In the variable capacitance element of the present embodiment, it is possible to obtain a plurality of configurations having different capacitance values by changing the formation position thereof without changing the electrode shape of the capacitor unit. Hereinafter, first and second configuration examples will be described sequentially.

### 2-1 First Configuration Example

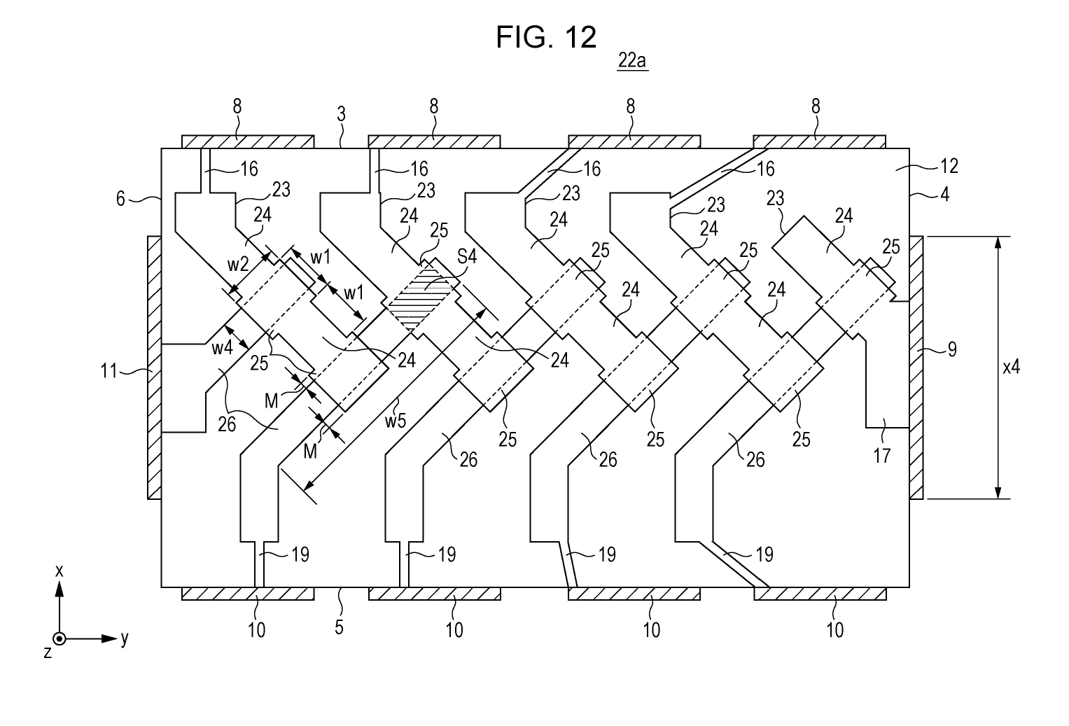

FIG. 12 is a structural diagram illustrating the variable capacitance element 22a according to the first configuration example of the present embodiment as seen from the z direction. In FIG. 12, like reference numerals denote like elements as in FIG. 3, and description thereof will not be repeated.

A plurality of first electrodes 23 (five in FIG. 12) are formed on top of the ferroelectric layer 12 stacked in the center of the laminate 2 and separated by a predetermined distance from one side to the other side in the y direction. Each first electrode 23 is formed to extend in the first direction rotated at about 45° clockwise from the y-directional side of the first side surface 3 of the laminate 2. In addition, each first electrode 23 is configured by alternately connecting the first and second electrode portions 25 and 24 in the first direction. The first electrode portion 25 has a rectangular shape having a first-directional electrode width w1 and a second-directional electrode width w2 perpendicular to the first direction w1, and the second electrode portion 24 has a rectangular shape having a first-directional electrode width w1 and a second-directional electrode width w3. In FIG. 12, the four first electrodes 23 formed sequentially from the fourth side surface 6 side of the laminate 2 are configured by alternately connecting four first electrode portions 25 and four second electrode portions 24. Furthermore, the first electrode 15 nearest to the second side surface 4 side is configured by connecting the first and second electrode portions 25 and 24.

As such, since the first electrode 23 includes the first and second electrode portions 25 and 24 having different second-directional electrode widths, each first electrode 23 is configured to have two electrode widths in the first direction. In addition, according to the present embodiment, each first electrode portion 25 of the first electrode 23 is positioned horizontally in the y direction, and each second electrode portions 24 is positioned horizontally in the y direction.

Each of four first electrodes 23 sequentially formed from the fourth side surface 6 side of the laminate 2 is connected to the internal terminal 16 formed in the same layer as that of the first electrode 23 so as to be exposed to the first side surface 3 of the laminate 2. In addition, the internal terminals 16 are connected to respective first external terminals 8 formed in the first side surface 3. The first electrode 23 nearest to the second side surface 4 of the laminate 2 is connected to the internal terminal 17 formed in the same layer as that of the first electrode 23 so as to be exposed to the second side surface 4 of the laminate 2. In addition, the internal terminal 17 is connected to the first external terminal 9 formed in the second side surface 4 of the laminate 2.

A plurality of second electrodes 26 (five in FIG. 12) are formed on the lower surface of the ferroelectric layer 12 stacked in the center of the laminate 2, and separated by a predetermined distance in the y direction from one side to the other side. The second electrode 26 has a rectangular shape having a first-directional electrode width w4(<w1) and a second-directional electrode width w5(>w2) and extends in the second direction.

The second electrode 26 is formed to intersect with a single first electrode 23 or to be across two neighboring first electrodes 23 in the y direction and is arranged such that the first electrode portion 25 of the first electrode 23 is overlapped with the second electrode 26 in the z direction.

The four second electrodes 26 near the second side surface 4 of the laminate 2 are connected to respective internal terminals 19 formed in the same layer as that of the second electrode 26 so as to be exposed to the third side surface 5 opposite to the first side surface 3 of the laminate 2. The internal terminals 19 are connected to the second external terminals 10 formed in the third side surface 5 of the laminate 2. The second electrode 26 nearest to the fourth side surface 6 of the laminate 2 is formed to be exposed to the fourth side surface 6. The second electrode 26 is connected to the second external terminal 11 formed in the fourth side surface 6 of the laminate 2.

As a result, in the variable capacitance element 22a of the first configuration example, as shown in FIG. 12, a capacitor unit is formed in the area where each of the first electrode portions 25 of the first electrode 23 and the second electrodes 26 stacked on the first electrode portions 25 by interposing the ferroelectric layers 12 are overlapped in the z direction. In addition, in the variable capacitance element 22a of FIG. 12, a plurality of second electrodes 26 and a plurality of first electrodes 23 are included such that one or two second electrodes 26 are overlapped with a single first electrode 23 in the z direction. As a result, a plurality of capacitor units are formed on the same surface. In addition, in the variable capacitance element 22a of the first configuration example, since the first electrode portions 25 of the first electrodes 23 and the second electrodes 26 are overlapped in the z direction, the electrode area of each capacitor unit becomes the overlapped area S4(=w2×w4) between the first and second electrodes 23 and 26.

### 2-2 Second Configuration Example

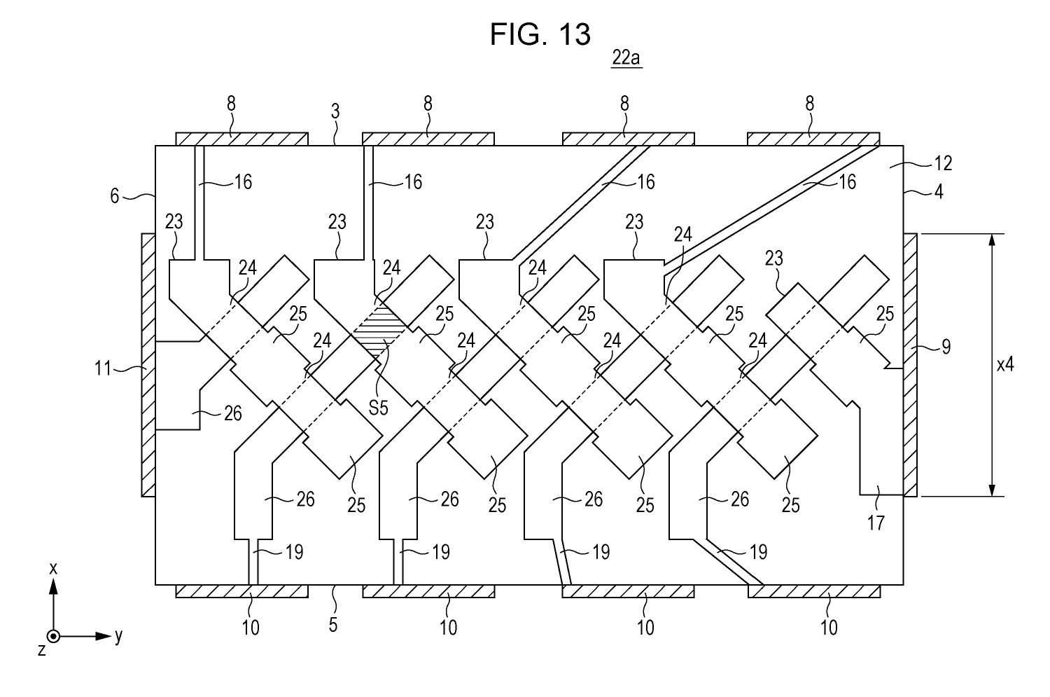

Next, a variable capacitance element according to the second configuration example of the present embodiment will be described. FIG. 13 is a structural diagram illustrating the variable capacitance element 22b according to the second configuration example of the present embodiment as seen from the z direction. In FIG. 13, like reference numerals denote like elements as in FIG. 12, and description thereof will not be repeated.

In the variable capacitance element 22b of the second configuration example, compared to the variable capacitance element 22a of the first configuration example, the first electrodes 23 are shifted in the third side surface side in the x direction with a distance x6 as shown in FIG. 13. The distance x6 is a distance in which the second electrode portions 24 of the first electrodes 23 and the second electrodes 26 are overlapped in the z direction. For this reason, the second electrodes 26 are arranged to be overlapped with the second electrode portions 24 of the first electrodes 23 in the z direction by interposing the ferroelectric layer 12 therebetween.

As a result, in the variable capacitance element 22b of the second configuration example, a capacitor unit is formed to include the second electrodes 26 and each of the second electrode portions 24 of the first electrodes 23 opposite to each other in the z direction by interposing the ferroelectric layer 12 therebetween. In addition, in the variable capacitance element 22b of the second configuration example, since the second electrodes 26 and the second electrode portions 24 of the first electrodes 23 are overlapped in the z direction, the electrode area of each capacitor unit becomes the overlapped area S5(=w3×w4) of the first and second electrodes 23 and 26.

The second-directional electrode width w3 of the second electrode portion 24 in the first electrode 23 is smaller than the second-directional electrode width w2 of the first electrode portion 25. For this reason, in the variable capacitance element 22b of the second configuration example, the electrode area of each capacitor unit is smaller than the electrode area of each capacitor unit of the variable capacitance element 22a of the first configuration example. As a result, the capacitance of the entire variable capacitance element 22a of the second configuration example becomes smaller than the capacitance of the entire variable capacitance element 22b of the first configuration example.

As such, according to the present embodiment, it is possible to provide two kinds of variable capacitance elements 22a and 22b having different capacitance values by deviating the formation position of the first electrode 23 even when the first and second electrodes 23 and 26 have the same shape.

The variable capacitance elements 22a and 22b of the present embodiment may be formed in a similar way to the first embodiment. Similarly, according to the present embodiment, it is not necessary to change the mask used to form electrodes between a case where the variable capacitance element 22a of the first configuration example is formed and a case where the variable capacitance element 22b of the second configuration example is formed. In a case where the variable capacitance element 22a of the first configuration example is formed, each electrode may be patterned on the ferroelectric layer 12 such that the first electrode portion 25 of the first electrode 23 and the second electrode 26 are stacked in the z direction. In addition, in a case where the variable capacitance element 22b of the second configuration example is formed, each electrode may be patterned on the ferroelectric layer 12 such that the second electrodes 26 and the second electrode portions 24 are stacked in the z direction.

Similarly, according to the present embodiment, in order to make it possible to form the variable capacitance elements 22a and 22b having different capacitance values by adjusting the formation position thereof even using the same electrode shape, it is necessary to consider the dimensions of the first and second electrodes 23 and 26 to some extent. Hereinafter, the shapes and the design overview of the dimensions of the first and second electrodes 23 and 26 of the variable capacitance elements 22a and 22b according to the present embodiment will be described.

The first-directional electrode widths w1 of the second electrode 26 and the first electrode portions 25 of the first electrodes 23 are preferably set to be larger than the first-directional electrode widths w4 of the second electrodes 26 in consideration of a undesired positional deviation in the manufacturing of the first and second electrodes 23 and 26. As a result, referring to FIG. 12, in a case where the first-directional center position of the first electrode portion 25 and the first-directional center position of the second electrode 26 are matched, a margin M((w1−w2)/2) (the area not overlapped with second electrode 26) is formed in both first-directional ends of the overlapped area S4. Such a margin M is preferably a width capable of absorbing a coupling deviation between the first and second electrodes 23 and 26, and is preferably set to, for example, 10 μm or longer. In addition, in consideration of manufacturing constraints, the electrode width w1 is preferably set to 50 μm or longer, and more preferably, 100 50 μm or longer.

In this manner, by forming the margin M, for example, in a case where the first electrode 23 is deviated from a predetermined position with respect to the second electrode 26 in the first direction, if the deviation amount thereof is smaller than the width of the margin M, the overlapped area between the first and second electrodes 23 and 26 do not change. For this reason, it is possible to facilitate formation of the variable capacitance element having a desired capacitance value. In addition, as shown in FIG. 13, the positions of the first electrodes 23 are different between the first and second configuration examples by the x-directional electrode width x6 of the first and second electrode portions 25 and 24. Such an electrode width x6 is sufficiently large compared to the margin M and is a width that can be intentionally deviated by changing the mask position. Therefore, according to the present embodiment, in the case of a small coupling deviation, it is possible to change the overlapped area between the first and second electrodes 23 and 26 by moving the electrode position as necessary without changing the overlapped area between the first and second electrodes 23 and 26.

In addition, depending on a difference between the first-directional electrode width of the first electrode portion 25 of the first electrode 23 and the second-directional electrode width of the second electrode portion 24, it is possible to change the capacitance value between the capacitance element 22a of the first configuration example and the variable capacitance element 22b of the second configuration example. Therefore, by setting a relationship between the electrode widths w2 and w3 to w2:w3=1:0.8, it is possible to set a ratio between the capacitance value of the variable capacitance element 22a of the first configuration example and the capacitance value of the variable capacitance element 22b of the second configuration example to 1:0.8. In this case, the electrode widths w2 and w3 may be set to different values, and various settings may be possible.

In addition, the second-directional electrode width w5 of the second electrode 26 may be larger than the first-directional maximum electrode width w2 of the first electrode 23, that is, the first-directional electrode width w2 of the first electrode portion 25. According to the present embodiment, since the second electrode 26 nearest to the fourth side surface 6 of the laminate 2 is connected the second external terminal 11 of the fourth side surface 6, it is necessary to form the second electrode 26 with a length so as to be exposed to the fourth side surface 6 of the laminate 2. In addition, since each of other second electrodes 26 is formed to be across two first electrodes 23, it is necessary to form the second-directional electrode width w5 to be larger than the second-directional width including two neighboring first electrodes 23.

In addition, according to the present embodiment, the second electrodes 26 having a rectangular shape are arranged such that the longitudinal direction thereof (second direction) is perpendicular to the longitudinal direction (first direction) of the first electrodes 23. For this reason, even when the first and second electrodes 23 and 26 are relatively deviated from predetermined positions in the second direction due to a coupling deviation, the overlapped area between the first and second electrodes 23 and 26 does not change. As a result, the capacitance value is not changed by a positional deviation in the second direction. In addition, dimensions of each electrode can be designed in a similar way to those of the electrode arrangement of the variable capacitance elements 1 (1a and 1b) of the first embodiment.

According to the present embodiment, the first electrodes 23 are arranged obliquely on the upper surface of the ferroelectric layer 12, and the second electrodes 26 are arranged obliquely on the lower surface of the ferroelectric layer 12 such that the second electrodes 26 are perpendicular to the first electrodes 23. As a result, compared to the variable capacitance elements 1 (1a and 1b) according to the first embodiment, it is possible to shorten the length of the internal terminal 19 of the second electrode 26. As a result, it is possible to reduce the electrode resistance. Similarly, according to the present embodiment, it is possible to provide the third configuration example of the first embodiment.

In addition, it is possible to obtain the same effects as those of the first embodiment.

Meanwhile, according to the first and second embodiments, it is possible to change the overlapped area between the first and second electrodes by forming the first electrodes to have two electrode widths in the longitudinal direction and arranging the second electrodes to intersect with the first electrodes in the transverse direction. The disclosure is not limited thereto, but may be variously modified. For example, the first electrodes may have two or more electrode widths in the longitudinal direction. In this case, using the same electrode shape, it is possible to form two or more kinds of variable capacitance elements having different capacitance values.

In addition, the second electrodes may be shaped to have a plurality of electrode widths. In this case, various configurations can be obtained by relatively moving the formation positions of the first and second electrodes in the x and y direction. In addition, if a plurality of electrode widths for the first electrodes are different from a plurality of electrode widths for the second electrodes, it is possible to form the variable capacitance elements having different capacitance values as many as a number obtained by multiplying the number of electrode widths of the first electrodes and the number of electrode widths of the second electrodes.

### 3. Third Embodiment

### Variable Capacitance Element

Next, the variable capacitance element according to the third embodiment of the disclosure will be described. Appearance of the variable capacitance element of the present embodiment is similar to that shown in FIG. 1, and description thereof will not be repeated. In the variable capacitance element of the present embodiment, it is possible to obtain a plurality of configurations having different capacitance values by changing the formation positions of electrodes included in the capacitor unit without changing the shapes thereof. Hereinafter, the first and second configuration examples will be described sequentially.

### 3-1 First Configuration Example

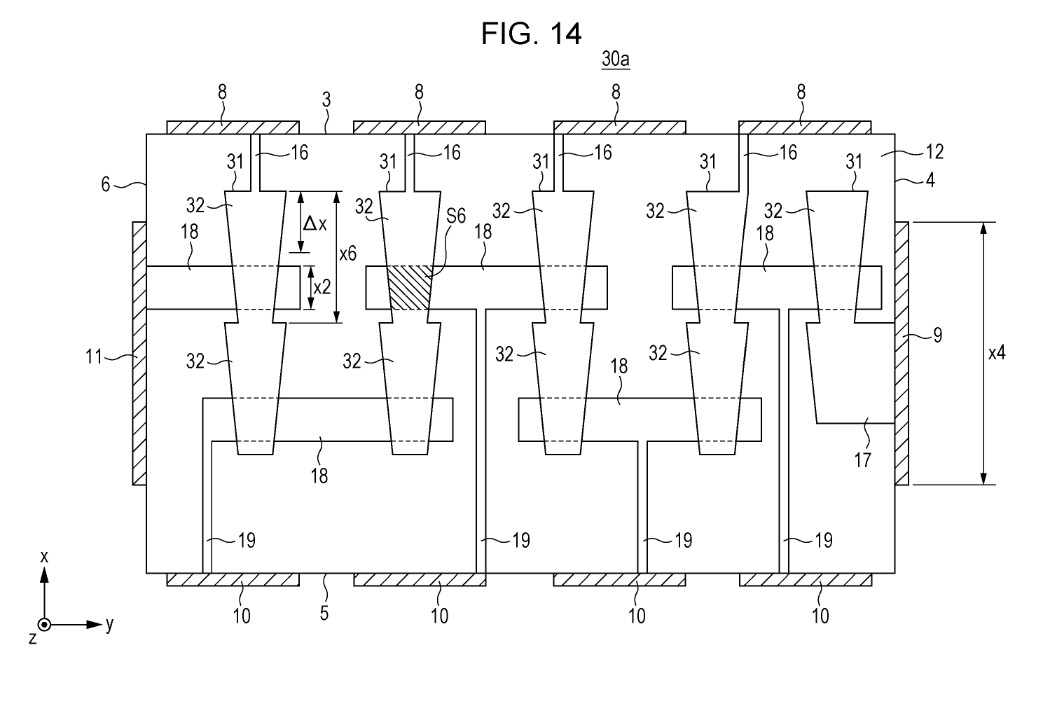

FIG. 14 is a structural diagram illustrating the variable capacitance element 30a according to the first configuration example of the present embodiment as seen from the z direction. In FIG. 14, like reference numerals denote like elements as in FIG. 3, and description thereof will not be repeated.

A plurality of first electrodes 31 (five in FIG. 14) are formed on top of the ferroelectric layer 12 stacked in the center of the laminate 2 and separated by a predetermined distance from one side to the other side in the y direction. Each first electrode 31 has a wide bottom side in the first side surface 3 side of the laminate 2 and a narrow top side in the third side surface 5 side, and includes trapezoidal electrode portions 32 having a x-directional width of x6(>x2). That is, the electrode portions 32 of the first electrodes 31 are continuously tapered from the first side surface 3 side of the laminate 2 to the third side surface 5 side. The four first electrodes 31 in the fourth side surface 6 side of the laminate 2 are formed by connecting two electrode portions 32 in the x direction, and the first electrode 31 nearest to the second side surface 4 includes only a single electrode portion 32.

Each of the four first electrodes 31 sequentially formed from the fourth side surface 6 side of the laminate 2 is connected to the internal terminal 16 formed in the same layer as that of the first electrode 31 so as to be exposed to the first side surface 3 of the laminate 2. In addition, the internal terminals 16 are connected to respective first external terminals 8 formed on the first side surface 3. The first electrode 31 nearest to the second side surface 4 of the laminate 2 is connected to the internal terminal 17 formed in the same layer as that of the first electrode so as to be exposed to the second side surface 4 of the laminate 2. Such an internal terminal 17 is connected to the first external terminal 9 formed on the second side surface 4 of the laminate 2.

The second electrodes 18 have the same shapes as those of the second electrodes 18 of the first embodiment, and are formed to be perpendicular to a single first electrode 31 or be perpendicular across two first electrodes 31 neighboring in the y direction. In the variable capacitance element 30a of the first configuration example, the first and second electrodes 31 and 18 are arranged such that the second electrodes 18 are overlapped with the area of the wide side of the first electrode 31 in the z direction.

As a result, in the variable capacitance element 30a of the first configuration example, as shown in FIG. 14, a capacitor unit is formed in the area where the first electrodes 31 and the second electrodes 18 stacked in the first electrodes 31 by interposing the ferroelectric layer 12 therebetween are overlapped in the z direction. In addition, the variable capacitance element 30a of FIG. 14 includes a plurality of first electrodes 31 and a plurality of second electrodes 18, and one or two second electrodes 18 are overlapped with a single first electrode 31 in the z direction. As a result, a plurality of capacitor units are formed in the same surface. In addition, in the variable capacitance element 30a of the first configuration example, the first and second electrodes 31 and 18 are overlapped in the z direction in the wide side of the electrode portion 32 of the first electrode 31, and the electrode area included in each capacitor unit becomes the overlapped area S6 between the first and second electrodes 31 and 18.

### 3-2 Second Configuration Example

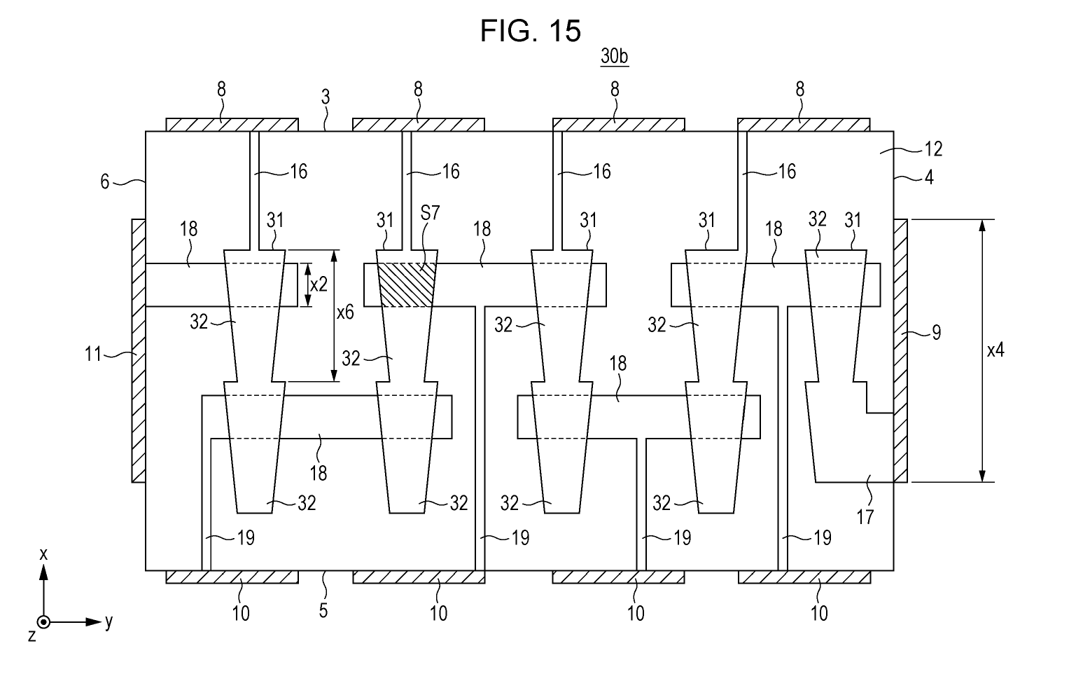

Next, a variable capacitance element according to the second configuration example of the present embodiment will be described. FIG. 15 is a structural diagram illustrating the variable capacitance element 30b according to the second configuration example of the present embodiment as seen from the z direction. In FIG. 15, like reference numerals denote like elements as in FIG. 14, and description thereof will not be repeated.

In the variable capacitance element 30b of the second configuration example, compared to the variable capacitance element 30a of the first configuration example, the first electrodes 31 are shifted in the third side surface 5 side in the x direction with a distance Δx(<x2). For this reason, the second electrodes 18 are arranged to be overlapped with the narrow sides of the first electrodes 31 in the z direction by interposing the ferroelectric layer 12 therebetween. However, the distance Δx is set to be within a range where the electrode portions 32 of the first electrodes 31 are overlapped with the second electrodes 18 in the z direction. That is, the distance Δx is set to be smaller than at least the length obtained by subtracting the x-directional length x2 of the second electrode 18 from the x-directional length x6 of the electrode portion 32.

As a result, in the variable capacitance element 30b of the second configuration example, a capacitor unit is formed to include the second electrodes 18 and the narrow sides of the electrode portions 32 of the first electrode 31 facing in the z direction by interposing the ferroelectric layer 12 therebetween. In addition, the variable capacitance element 30b of the second configuration example is configured such that the first and second electrodes 31 and 18 are overlapped in the z direction in the narrow side of the electrode portion 32 of the first electrode 31, and the electrode area of each capacitor unit becomes the overlapped area S7 between the first and second electrodes 31 and 18.

In the second configuration example, the first and second electrodes 31 and 18 are overlapped in the narrow side of the electrode portion 32 of the first electrode 31. For this reason, in the variable capacitance element 30b of the second configuration example, the electrode area of each capacitor unit is smaller than the electrode area of each capacitor unit of the variable capacitance element 30a in the first configuration example. As a result, the capacitance of the entire variable capacitance element 30b in the second configuration example becomes smaller than the capacitance of the entire variable capacitance element 30a in the first configuration example.

As such, according to the present embodiment, even when the first and second electrodes 31 and 18 have the same shape, it is possible to provide two kinds of variable capacitance elements 30a and 30b having different capacitances by changing the formation position of the first electrodes 31.

The variable capacitance elements 30a and 30b of the present embodiment can be formed in a similar way to the first embodiment. Similarly, according to the present embodiment, it is not necessary to change the mask used to form electrodes between a case where the variable capacitance element 30a of the first configuration example is formed and a case where the variable capacitance element 30b of the second configuration example is formed. In a case where the variable capacitance element 30a of the first configuration example is formed, each electrode may be formed on a sheet such that the wide side of the electrode portion 32 of the first electrode 31 and the second electrode 18 are stacked in the z direction. In addition, in a case where the variable capacitance element 30b of the second configuration example is formed, each electrode may be formed on a sheet such that the narrow side of the electrode portion 32 of the first electrode 31 and the second electrode 18 are stacked in the z direction.

According to the present embodiment, the first electrode 31 has a trapezoidal shape (tapered shape), and the overlapped area is continuously changed by shifting the overlapped position between the first and second electrodes 31 and 18 in a direction to which the electrode width of the first electrode 31 is changed. As a result, it is possible to form the variable capacitance elements having slight different capacitance values by changing the overlapped positions without changing the electrode shape.

Similarly, according to the present embodiment, the longitudinal direction of the first electrode 31 intersects with the longitudinal direction of the second electrode 18. For this reason, when the positions of the first and second electrodes 31 and 18 are relatively deviated in the y direction, the capacitance value does not change. On the contrary, only when the positions of the first and second electrodes 31 and 18 are relatively shifted in the x direction, the capacitance value changes. As a result, it is possible to form the variable capacitance elements 30a and 30b having different capacitance values just by changing the relative positional relationship between the first and second electrodes 31 and 18 in the x direction, and facilitate design.

In addition, it is possible to obtain the same effects as those of the first embodiment.

Although the electrostatic capacitance element has been exemplified as the variable capacitance element in the first to third embodiments, the disclosure is not limited thereto. The configurations of the first and second electrodes described in the first to third embodiments may be similarly applied to the electrostatic capacitance element (hereinafter, referred to as an constant capacitance element) of which the capacitance is almost not changed regardless of the type of the input signal and the signal level thereof.

However, in this case, the dielectric layer is formed of a paraelectric material having a low relative permittivity. The paraelectric material may include, for example, paper, polyethylene terephthalate, polypropylene, polyphenylene sulfide, polystyrene, TiO₂, MgTiO₂, MgTiO₃, SrMgTiO₂, Al₂O₃, Ta₂O₅, and the like. In addition, such a constant capacitance element may be manufactured in a similar way to that of the variable capacitance element of the first embodiment. Although all of the external terminals are used as DC terminals in the aforementioned variable capacitance element, it is evident that no DC terminal is necessary in the case of the constant capacitance element, and only two terminals may be used as AC terminals.

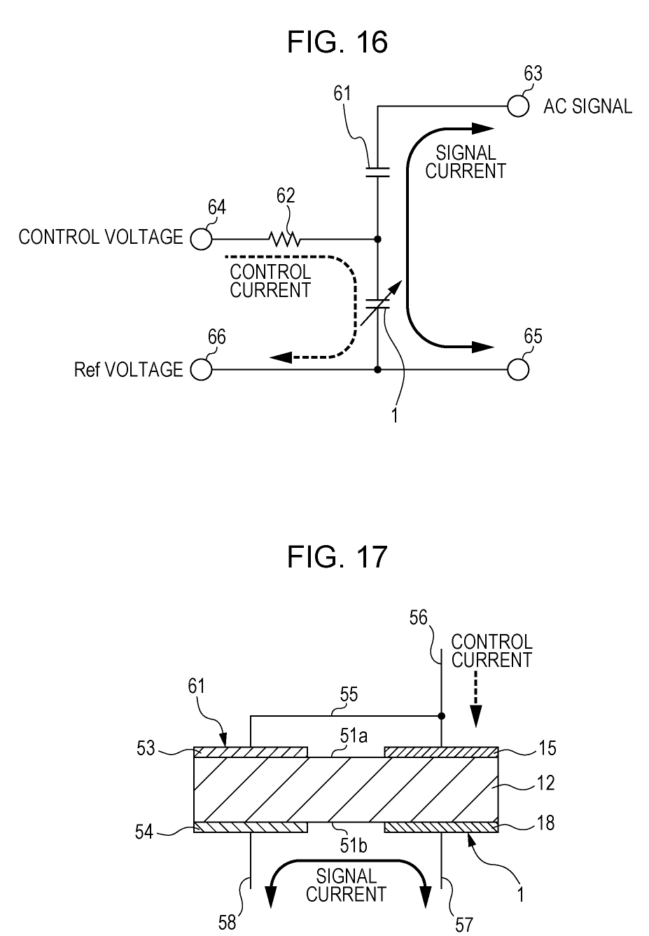

FIG. 16 illustrates a circuit configuration example of the periphery of the variable capacitance element in an actual circuit.

In an actual circuit, one terminal of the variable capacitance element 1 is connected to one input/output terminal 63 of the Ac signal through a bias removal capacitor 61 and also connected to the input terminal 64 of the control voltage through a current-limiting resistor 62. In addition, the other terminal of the variable capacitance element 50 is connected to the other input/output terminal 65 of the AC signal and also connected to the output terminal 66 of the control voltage.

In such a circuit configuration of the variable capacitance element 1, the signal current (AC signal) flows to both the bias removal capacitor 61 and the variable capacitance element 1, and the control current (DC bias current) flows only to the variable capacitance element 1 through the current-limiting resistor 62. In this case, the capacitance Cv of the variable capacitance element 1 changes by changing the control voltage, and as a result, the signal current also changes.

Configuration of Variable Capacitance Element

In this regard, next, an example of integrating the variable capacitance element 1 and the bias removal capacitor 61 into each other will be described. FIG. 17 illustrates a configuration example of an element obtained by integrating the variable capacitance element 1 and the bias removal capacitor 61. In FIG. 17, like reference numerals denote like elements as in the first embodiment (FIG. 3).

The variable capacitance element 1 includes a ferroelectric layer 12 and first and second electrodes 15 and 18 for the variable capacitance element 1 formed to face each other by interposing the ferroelectric layer 12 therebetween. In addition, the variable capacitance element 1 includes first and second electrodes 53 and 54 of the bias removal capacitor 61 formed to face each other by interposing the ferroelectric layer 12 therebetween.

The first electrode 15 for the variable capacitance element 1 and the first electrode 53 of the bias removal capacitor 61 are formed on the upper surface 51a of the ferroelectric layer 12 at a predetermined distance. In addition, the second electrode 18 for the variable capacitance element 1 and the second electrode 54 of the bias removal capacitor 61 are formed on the lower surface 51b of the ferroelectric layer 51 at a predetermined distance. That is, according to the present embodiment, the dielectric layer is shared between the bias removal capacitor 61 and the variable capacitance element 1.

In addition, the first electrode 15 for the variable capacitance element 1 and the first electrode 53 of the bias removal capacitor 61 are connected to each other through a lead wire 55 and the like. In addition, a predetermined wiring pattern for connecting the first electrode 15 for the variable capacitance element 1 and the first electrode 53 of the bias removal capacitor 61 may be formed on the upper surface 51a of the ferroelectric layer 12 and connected to each other.

The first electrode 15 for the variable capacitance element 1 and the first electrode 53 for the bias removal capacitor 61 are connected to the input terminal 64 of the control voltage through the current-limiting resistor 62 using the lead wire 56 (refer to FIGS. 16 and 17). The second electrode 18 for the variable capacitance element 1 is connected to the output terminal 66 of the control voltage and the other input/output terminal 65 of the AC signal through the lead wire 57. In addition, the second electrode 54 of the bias removal capacitor 61 is connected to one input/output terminal 63 of the AC signal through the lead wire 58. By connecting them in this way, similar to the circuit configuration of FIG. 16, the signal current (AC signal) flows to the bias removal capacitor 61 and the variable capacitance element 1, and the control current (DC bias current) flows only the variable capacitance element 1 through the current-limiting resistor 62.

In addition, the first electrode 15 and the second electrode 18 for the variable capacitance element 1 may be configured using the same shapes as those of the first and second electrodes used in the variable capacitance element of the second and third embodiments. Meanwhile, the first and second electrodes 53 and 54 of the bias removal capacitor 61 may be formed using the same shapes as those of the capacitor of the related art.

As such, by integrating the variable capacitance element 1 and the bias removal capacitor 61, it is possible to reduce the dimensions of the device to which the variable capacitance element of the disclosure is applied. In addition, it is possible to reduce the number of components and cost of the device.

### 4. Fourth Embodiment

### Resonance Circuit

In the fourth embodiment, a configuration example of a noncontact receiver apparatus having the aforementioned electrostatic capacitance element according to the disclosure will be described.

Configuration of Noncontact Receiver Apparatus

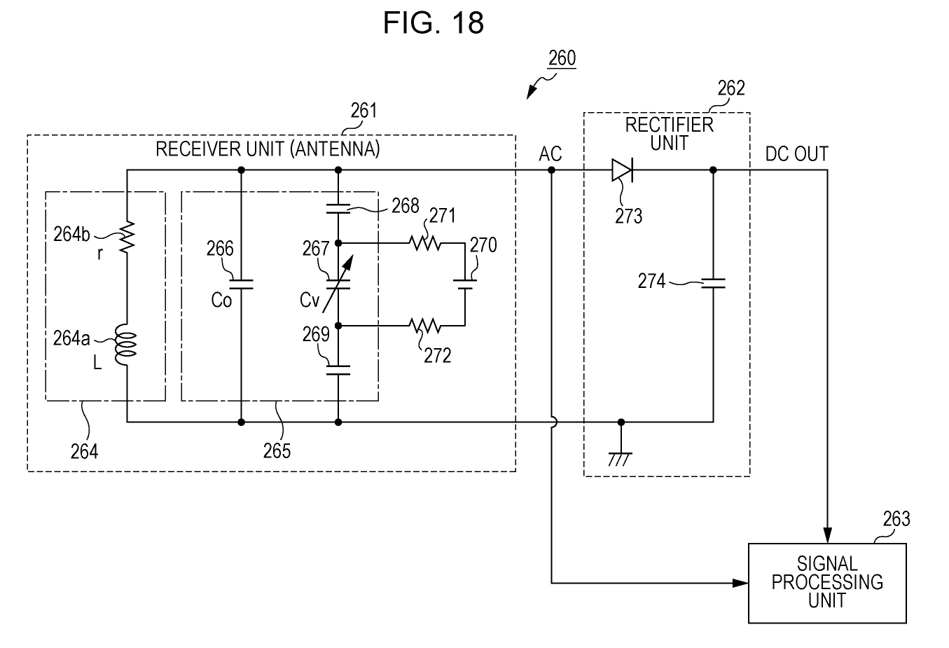

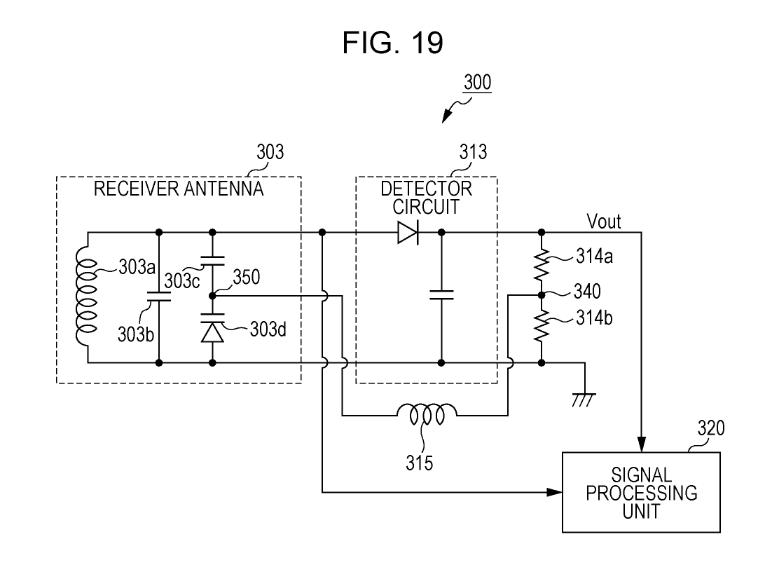

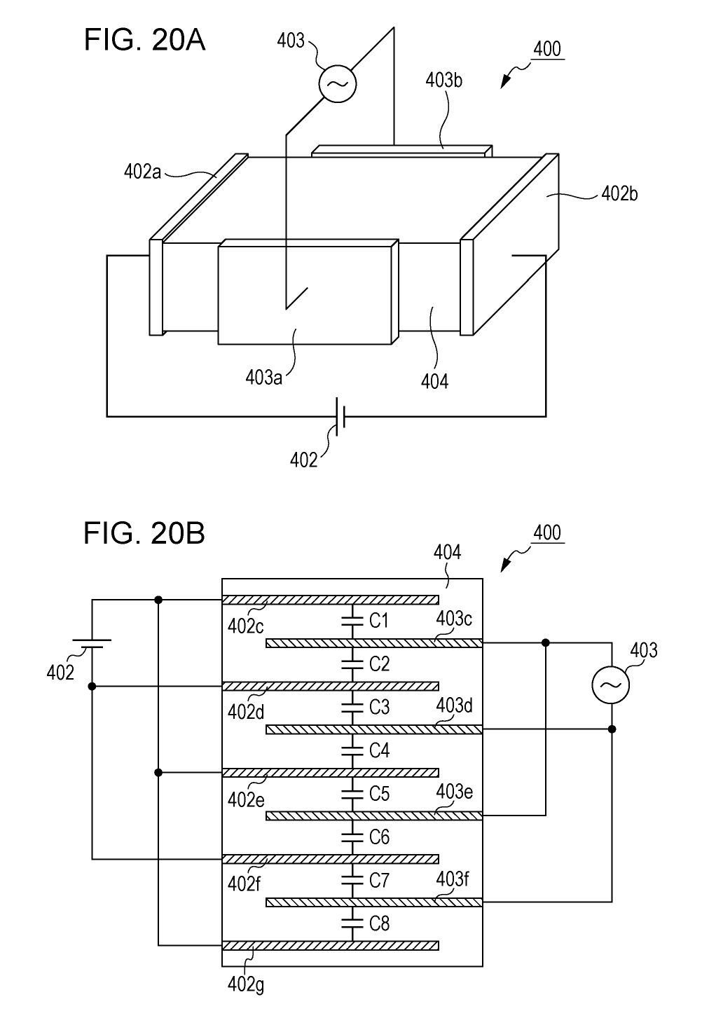

In the present embodiment, a noncontact IC card will be exemplified as the noncontact receiver apparatus. FIG. 18 illustrates a block configuration of the circuit unit of the receiver system (demodulation system) of the noncontact IC card according to the present embodiment. In FIG. 18, for simplicity purposes, a circuit unit of a signal transmitter system (modulation system) is omitted intentionally. The configuration of the circuit unit of transmitter system may be similarly configured to that of the noncontact IC card of the related art.

The noncontact IC card 260 includes a receiver unit 261 (antenna), a rectifier unit 262, and a signal processing unit 263.

The receiver unit 261 includes a resonance circuit having a resonance coil 264 and a resonance capacitor 265, and receives the signal transmitted from the reader/writer (not shown) of the noncontact IC card 260 through this resonance circuit. In FIG. 18, the resonance coil 264 is illustrated as being divided into an inductance component 264a (L) and a resistance component 264b (r: about several ohms). In addition, the receiver unit 261 includes the control power source 270 of the variable capacitance element 267 within the resonance capacitor 265 as described below and the two current-limiting resistors 271 and 272 provided between the variable capacitance element 267 and the control power source 270.

The resonance capacitor 265 includes a constant capacitance capacitor 266 having a capacitance Co, a variable capacitance element 267, and two bias removal capacitors 268 and 269 connected to both terminals of the variable capacitance element 267. In addition, a series circuit containing the constant capacitance capacitor 266, the variable capacitance element 267, and the two bias removal capacitors 268 and 269 is connected in parallel to the resonance coil 264.

The constant capacitance capacitor 266 includes any one of the two-terminal type constant capacitance capacitors (constant capacitance elements) having the electrodes and the external terminals described above in conjunction with various embodiments and various modifications. The dielectric layer included in the constant capacitance capacitor 266 is formed of a dielectric material (paraelectric material) having a low relative permittivity as described in conjunction with the first embodiment, and the capacitance thereof almost does not change regardless of the type of the input signal (AC or DC) and the signal level.

In a practical circuit, there is a capacitance variation (about several pF) in the receiver unit 261 due to a deviation of the inductance component L of the resonance coil 264 or a parasitic capacitance of the input terminal of the integrated circuit within the signal processing unit 263, and the variation amount is different in each noncontact IC card 260. Therefore, according to the present embodiment, in order to suppress (correct) such an effect, the capacitance Co is appropriately adjusted by trimming the electrode pattern of the internal electrode within the constant capacitance capacitor 266.

The variable capacitance element 267 includes any one of the two-terminal type variable capacitance elements described above in conjunction with various embodiments. In addition, the dielectric layer included in the variable capacitance element 267 is made of a ferroelectric material having a large relative permittivity as described in conjunction with the first embodiment. The disclosure is not limited thereto, but the variable capacitance element 267 may include a four-terminal type variable capacitance element.

In addition, the variable capacitance element 267 is connected to the control power source 270 through the current-limiting resistors 271 and 272. In addition, the capacitance Cv of the variable capacitance element 267 changes depending on the control voltage applied from the control power source 270.

In addition, the bias removal capacitors 268 and 269 and the current-limiting resistors 271 and 272 are provided to suppress the influence from interference between the receive signal current and the DC bias current (control current) flowing from the control power source. Specifically, the bias removal capacitors 268 and 269 are provided to protect and/or separate the signal circuit, and the current-limiting resistors 271 and 272 are provided to protect and/or separate the control circuit.

The rectifier unit 262 includes a half-wave rectifier circuit having a rectification diode 273 or a rectification capacitor 274 to rectify the AC voltage received by the receiver unit 261 into the DC voltage and output it.

The signal processing unit 263 mainly includes a semiconductor large scale integration (LSI) circuit to demodulate the AC signal received by the receiver unit 261. The LSI circuit of the signal processing unit 263 is driven by the DC voltage supplied from the rectifier unit 262. In addition, a noncontact IC card of the related art may be used as the LSI.

In the noncontact IC card 260 of the present embodiment, the variable capacitance element 267 is used to prevent breakdown of the control circuit made of a semiconductor device having a low voltage-withstanding property against an excessively strong receive signal. Specifically, in a case where the receive signal is excessively strong, the capacitance Cv of the variable capacitance element 267 is reduced by the control voltage. As a result, the resonant frequency of the receiver unit 261 is shifted into a high frequency range by a frequency Δf corresponding to the lowered capacitance of the variable capacitance element 267. As a result, a response of the receive signal at the resonant frequency f₀ after the capacitance changes is lowered than that before the capacitance change, and thus, the level of the receive signal is suppressed. As a result, it is possible to prevent an excessively strong current signal from flowing to the control circuit and prevent breakdown of the control circuit.

In the noncontact IC card 260 of the present embodiment, since the electrostatic capacitance element having the electrode configuration of the present disclosure is used in the constant capacitance capacitor 266 and the variable capacitance element 267, it is possible to provide a higher-performance noncontact IC card. In addition, since the electrostatic capacitance element having the electrode configuration of the disclosure is used in the variable capacitance element 267, it is possible to drive the noncontact IC card using a lower drive voltage.

Although the electrostatic capacitance element having the electrode configuration of the disclosure is employed in both the constant capacitance capacitor 266 and the variable capacitance element 267 in the present embodiment, the disclosure is not limited thereto. For example, the electrostatic capacitance element of the disclosure may be employed in either of them. Furthermore, according to the present embodiment, the constant capacitance capacitor 266 may not be included.

Although the control power source 270 of the variable capacitance element 267 is provided in the noncontact IC card 260 of the present embodiment, the disclosure is not limited thereto. For example, similar to the Japanese Unexamined Patent Application Publication No. 08-7059, a desired control voltage may be extracted from the DC voltage output from the rectifier unit 262, for example, using techniques such as voltage dividing.

Although the noncontact IC card is used as an example of the noncontact receiver apparatus according to the present embodiment, the disclosure is not limited thereto. The disclosure may be applied to any apparatus that receives information and/or power noncontactly using the resonance circuit having the resonance coil and the resonance capacitor, and in this case, the same effect can be achieved. For example, the disclosure may be applied to a mobile phone, a wireless power transmission apparatus, and the like. In addition, since power is noncontactly transmitted in the wireless power transmission apparatus, a signal process unit for demodulating the receive signal may be dispensable unlike the noncontact IC card.

The present disclosure contains subject matter related to that disclosed in Japanese Priority Patent Application JP 2010-203580 filed in the Japan Patent Office on Sep. 10, 2010, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

1. An electrostatic capacitance element comprising:
a dielectric layer; and
a pair of electrodes or a plurality of pairs of electrodes having one electrode formed on one surface of the dielectric layer and another electrode formed on another surface of the dielectric layer by interposing the dielectric layer therebetween,
wherein the one electrode and the other electrode are arranged such that longitudinal directions of the electrodes intersect with each other, and the one electrode and/or the other electrode have at least two electrode widths, so that, in a case where the one electrode is formed to be relatively shifted with respect to the other electrode, an area of the electrodes overlapping in a thickness direction of the dielectric layer by interposing the dielectric layer can be changed in a continuous manner or a stepwise manner.

2. The electrostatic capacitance element according to claim 1, wherein the area of the electrodes overlapping by interposing the dielectric layer can be changed in a stepwise manner only when the one electrode is shifted by a predetermined distance.

3. The electrostatic capacitance element according to claim 1, wherein the one electrode and the other electrode are arranged such that longitudinal directions of the electrodes intersect with each other.

4. The electrostatic capacitance element according to claim 1, wherein the pair of electrodes or the plurality of pairs of electrodes are stacked in a thickness direction of the dielectric layer.

5. The electrostatic capacitance element according to claim 1, wherein the dielectric layer is formed of a ferroelectric material, and a capacitance of the dielectric layer changes depending on a control signal applied from an external side.

6. A method of manufacturing an electrostatic capacitance element comprising a dielectric layer and a pair of electrodes or a plurality of pairs of electrodes having one electrode formed on one surface of the dielectric layer and another electrode formed on another surface of the dielectric layer by interposing the dielectric layer therebetween, the one electrode and the other electrode being arranged such that longitudinal directions of the electrodes intersect with each other, and the one electrode and/or the other electrode have at least two electrode widths, so that, in a case where the one electrode is formed to be relatively shifted with respect to the other electrode, an area of the electrodes overlapping in a thickness direction of the dielectric layer by interposing the dielectric layer can be changed in a continuous manner or a stepwise manner, the method comprising:
using a mask to pattern the one electrode and the other electrode, while the one electrode and the other electrode are positioned in predetermined locations on a surface of the dielectric layer, and
forming the one electrode and/or the other electrode, while a location of the mask positioned on the surface of the dielectric layer is adjusted such that an electrode area where the one electrode and the other electrode are overlapped in a thickness direction of the dielectric layer has a predetermined area.

7. The method according to claim 6, wherein the one electrode and/or the other electrode are shaped such that the electrode area overlapping by interposing the dielectric layer can be changed in a stepwise manner only when the one electrode is shifted a predetermined distance.

8. The method according to claim 6, wherein the one electrode and the other electrode are formed such that longitudinal directions of the electrodes are intersect with each other.

9. The method according to claim 6, wherein the pair of electrodes or the plurality of pairs of electrodes are stacked in a thickness direction of the dielectric layer.

10. The method according to claim 6, wherein the dielectric layer is made of a ferroelectric material of which a capacitance changes depending on a control signal applied from an external side.

11. A resonance circuit comprising:
a resonance capacitor; and
a resonance coil connected to the resonance capacitor,
wherein the resonance capacitor includes an electrostatic capacitance element having
a dielectric layer, and
a pair of electrodes or a plurality of pairs of electrodes having one electrode formed on one surface of the dielectric layer and another electrode formed on another surface of the dielectric layer by interposing the dielectric layer therebetween, wherein the one electrode and the other electrode are arranged such that longitudinal directions of the electrodes intersect with each other, and the one electrode and/or the other electrode have at least two electrode widths, so that, in a case where the one electrode is formed to be relatively shifted with respect to the other electrode, an area of the electrodes overlapping in a thickness direction of the dielectric layer by interposing the dielectric layer can be changed in a continuous manner or a stepwise manner.
